(19) United States
(12) Patent Application Publication
(10) Pub. No.: US 2026/0252236 A1
(43) Pub. Date: Aug. 27, 2026

(54) System and Method for Codebook-Based Data Encoding with Temporal Pattern Recognition

(71) Applicant: AtomBeam Technologies Inc., Moraga, CA (US)

(72) Inventors: Joshua Cooper, Columbia, SC (US); Charles Yeomans, Orinda, CA (US)

(21) Appl. No.: 19/227,409

(22) Filed: Jun. 3, 2025

Related U.S. Application Data
(63) Continuation-in-part of application No. 18/545,540, filed on Dec. 19, 2023, now Pat. No. 12,321,596.
Application No. 18/545,540 is a continuation of application No. 18/147,707, filed on Dec. 29, 2022, now Pat. No. 11,853,550.
Application No. 18/147,707 is a continuation of application No. 17/727,913, filed on Apr. 25, 2022, now Pat. No. 11,620,051.
Application No. 17/727,913 is a continuation of application No. 17/404,699, filed on Aug. 17, 2021, now Pat. No. 11,385,794.

(51) Int. Cl. G06F 3/06; H03M 7/30; H03M 7/40

(52) U.S. Cl. CPC G06F 3/0608; G06F 3/0623; G06F 3/0656; G06F 3/0659; G06F 3/067; G06F 3/0679; H03M 7/405; H03M 7/6005; H03M 7/6011

(57) ABSTRACT

A system and method for codebook-based data encoding with temporal pattern recognition. Time-series data is analyzed to identify recurring patterns across multiple time scales, enabling the creation of temporally-optimized codebooks. Portions of data are encoded by different encoding libraries, dynamically selected based on the data's temporal characteristics, providing substantial improvements in compression efficiency over single-algorithm approaches. This methodology also enhances security as multiple decoding libraries must be used to decode the data. In some embodiments, each portion of data may be encoded using different sourceblock sizes aligned with natural temporal boundaries, further improving compression and security. Encoding libraries may be rotated according to identified temporal cycles or pseudo-randomly to maximize both efficiency and protection. The system continuously evaluates compression improvements and refines its approach based on measured performance across different temporal contexts.

### CROSS-REFERENCE TO RELATED APPLICATIONS

Priority is claimed in the application data sheet to the following patents or patent applications, of each of which is expressly incorporated herein by reference in its entirety:
Ser. No. 18/545,540
Ser. No. 18/147,707
Ser. No. 17/727,913
Ser. No. 17/404,699

### BACKGROUND OF THE INVENTION

### Field of the Invention

The present invention is in the field of computer data encoding, and in particular the usage of encoding for enhanced security and compaction of data.

### Discussion of the State of the Art

As computers become an ever-greater part of our lives, and especially in the past few years, data storage has become a limiting factor worldwide. Prior to about 2010, the growth of data storage far exceeded the growth in storage demand. In fact, it was commonly considered at that time that storage was not an issue, and perhaps never would be, again. In 2010, however, with the growth of social media, cloud data centers, high tech and biotech industries, global digital data storage accelerated exponentially, and demand hit the zettabyte (1 trillion gigabytes) level. Current estimates are that data storage demand will reach 50 zettabytes by 2020. By contrast, digital storage device manufacturers produced roughly 1 zettabyte of physical storage capacity globally in 2016. We are producing data at a much faster rate than we are producing the capacity to store it. In short, we are running out of room to store data, and need a breakthrough in data storage technology to keep up with demand.

The primary solutions available at the moment are the addition of additional physical storage capacity and data compression. As noted above, the addition of physical storage will not solve the problem, as storage demand has already outstripped global manufacturing capacity. Data compression is also not a solution. A rough average compression ratio for mixed data types is 2:1, representing a doubling of storage capacity. However, as the mix of global data storage trends toward multi-media data (audio, video, and images), the space savings yielded by compression either decreases substantially, as is the case with lossless compression which allows for retention of all original data in the set, or results in degradation of data, as is the case with lossy compression which selectively discards data in order to increase compression. Even assuming a doubling of storage capacity, data compression cannot solve the global data storage problem. The method disclosed herein, on the other hand, works the same way with any type of data.

Transmission bandwidth is also increasingly becoming a bottleneck. Large data sets require tremendous bandwidth, and we are transmitting more and more data every year between large data centers. On the small end of the scale, we are adding billions of low bandwidth devices to the global network, and data transmission limitations impose constraints on the development of networked computing applications, such as the “Internet of Things”.

Furthermore, as quantum computing becomes more and more imminent, the security of data, both stored data and data streaming from one point to another via networks, becomes a critical concern as existing encryption technologies are placed at risk.

Data encoding is currently performed using a single encoding algorithm per file, and often the same algorithm is used for large sets of files, entire storage devices, and entire systems. The advantage to using a single encoding algorithm is that only a single decoding algorithm is needed to decode the data. However, the use of a single encoding algorithm does not allow for maximum encoding compaction and creates a security vulnerability because all data can be decoded using a single algorithm.

What is needed is a system and method for encoding data using different compaction algorithms for different portions of the data.

### SUMMARY OF THE INVENTION

The inventor has developed a system and method for codebook-based data encoding with temporal pattern recognition. As each portion of the data is maximally compacted, this results in the greatest compaction of the data set as a whole. This methodology not only provides substantial improvements in data compaction over use of a single data compaction algorithm with the highest average compaction, but provides substantial additional security in that multiple decoding libraries must be used to decode the data. In some embodiments, each portion of data may further be encoded using different sourceblock sizes, providing further security enhancements as decoding requires multiple decoding libraries and knowledge of the sourceblock size used for each portion of the data. In some embodiments, encoding libraries may be randomly or pseudo-randomly rotated to provide additional security.

According to a preferred embodiment, a computer system comprising a hardware memory, wherein the computer system is configured to execute software instructions stored on nontransitory machine-readable storage media that: analyze time-series data to identify recurring temporal patterns across multiple time scales; select a list of codebooks for encoding a plurality of sourcepackets based on the identified temporal patterns, each sourcepacket comprising a sourcepacket identifier and one or more of the identified temporal patterns, the list comprising a codebook identifier for each codebook; for each sourcepacket: encode the sourcepacket with a codebook in the list of codebooks dynamically selected based on the sourcepacker's temporal characteristics; associate the sourcepacket identifier with the encoded sourcepacket; associate the codebook identifier of the codebook which produced the encoded sourcepacket with the sourcepacket identifier; and send a data pair comprising the respective sourcepacket identifier and its associated codebook identifier to a combiner, is disclosed.

According to another preferred embodiment, a method for codebook-based data encoding, comprising the steps of: analyze time-series data to identify recurring temporal patterns across multiple time scales; select a list of codebooks for encoding a plurality of sourcepackets based on the identified temporal patterns, each sourcepacket comprising a sourcepacket identifier and one or more of the identified temporal patterns, the list comprising a codebook identifier for each codebook; for each sourcepacket: encode the sourcepacket with a codebook in the list of codebooks dynamically selected based on the sourcepacker's temporal characteristics; associate the sourcepacket identifier with the encoded sourcepacket; associate the codebook identifier of the codebook which produced the encoded sourcepacket with the sourcepacket identifier; and send a data pair comprising the respective sourcepacket identifier and its associated codebook identifier to a combiner, is disclosed.

According to an aspect of an embodiment, the codebooks used to encode the data are combined as a single codebook.

According to an aspect of an embodiment, the data structure further comprises a copy of the stored encoded sourcepacket associated with each sourcepacket identifier.

According to an aspect of an embodiment, the sourcepacket identifier is a universal unique identifier (UUID).

According to an aspect of an embodiment, the codebook identifier is a universal unique identifier (UUID).

### BRIEF DESCRIPTION OF THE DRAWING FIGURES

The accompanying drawings illustrate several aspects and, together with the description, serve to explain the principles of the invention according to the aspects. It will be appreciated by one skilled in the art that the particular arrangements illustrated in the drawings are merely exemplary, and are not to be considered as limiting of the scope of the invention or the claims herein in any way.

FIG. 1 is a diagram showing an embodiment of the system in which all components of the system are operated locally.

FIG. 2 is a diagram showing an embodiment of one aspect of the system, the data deconstruction engine.

FIG. 3 is a diagram showing an embodiment of one aspect of the system, the data reconstruction engine.

FIG. 4 is a diagram showing an embodiment of one aspect of the system, the library management module.

FIG. 5 is a diagram showing another embodiment of the system in which data is transferred between remote locations.

FIG. 6 is a diagram showing an embodiment in which a standardized version of the sourceblock library and associated algorithms would be encoded as firmware on a dedicated processing chip included as part of the hardware of a plurality of devices.

FIG. 7 is a diagram showing an example of how data might be converted into reference codes using an aspect of an embodiment.

FIG. 8 is a method diagram showing the steps involved in using an embodiment to store data.

FIG. 9 is a method diagram showing the steps involved in using an embodiment to retrieve data.

FIG. 10 is a method diagram showing the steps involved in using an embodiment to encode data.

FIG. 11 is a method diagram showing the steps involved in using an embodiment to decode data.

FIG. 12 is a diagram showing an exemplary system architecture, according to a preferred embodiment of the invention.

FIG. 13 is a diagram showing a more detailed architecture for a customized library generator.

FIG. 14 is a diagram showing a more detailed architecture for a library optimizer.

FIG. 15 is a diagram showing a more detailed architecture for a transmission and storage engine.

FIG. 16 is a method diagram illustrating key system functionality utilizing an encoder and decoder pair.

FIG. 17 is a method diagram illustrating possible use of a hybrid encoder/decoder to improve the compression ratio.

FIG. 18 is a flow diagram illustrating the use of a data encoding system used to recursively encode data to further reduce data size.

FIG. 19 is an exemplary system architecture of a data encoding system used for cyber security purposes.

FIG. 20 is a flow diagram of an exemplary method used to detect anomalies in received encoded data and producing a warning.

FIG. 21 is a flow diagram of a data encoding system used for Distributed Denial of Service (DDOS) attack denial.

FIG. 22 is an exemplary system architecture of a data encoding system used for data mining and analysis purposes.

FIG. 23 is a flow diagram of an exemplary method used to enable high-speed data mining of repetitive data.

FIG. 24 is an exemplary system architecture of a data encoding system used for remote software and firmware updates.

FIG. 25 is a flow diagram of an exemplary method used to encode and transfer software and firmware updates to a device for installation, for the purposes of reduced bandwidth consumption.

FIG. 26 is an exemplary system architecture of a data encoding system used for large-scale software installation such as operating systems.

FIG. 27 is a flow diagram of an exemplary method used to encode new software and operating system installations for reduced bandwidth required for transference.

FIG. 28 is a block diagram of an exemplary system architecture of a codebook training system for a data encoding system, according to an embodiment.

FIG. 29 is a block diagram of an exemplary architecture for a codebook training module, according to an embodiment.

FIG. 30 is a block diagram of another embodiment of the codebook training system using a distributed architecture and a modified training module.

FIG. 31 is a method diagram illustrating the steps involved in using an embodiment of the codebook training system to update a codebook.

FIG. 32 is an exemplary system architecture for an encoding system with multiple codebooks.

FIG. 33 is a flow diagram describing an exemplary algorithm for encoding of data using multiple codebooks.

FIG. 34 is a diagram describing an exemplary codebook sorting algorithm for determining a plurality of codebooks to be shuffled between during the encoding process.

FIG. 35 is a diagram showing an exemplary codebook shuffling method.

FIG. 36 is a diagram showing an exemplary system architecture incorporating temporal pattern recognition capabilities for codebook-based data encoding.

FIG. 37 is a diagram showing an exemplary architecture of temporal pattern recognizer, illustrating its internal components and data flow.

FIG. 38 is a flow diagram illustrating an exemplary method for temporal pattern recognition for encoding data.

FIG. 39 is a flow diagram illustrating an exemplary method for temporal pattern recognition for data encoding optimization.

FIG. 40 is a flow diagram illustrating an exemplary method for temporally optimizing codebooks for data encoding.

FIG. 41 illustrates an exemplary computing environment on which an embodiment described herein may be implemented.

### DETAILED DESCRIPTION OF THE INVENTION

The inventor has conceived, and reduced to practice, a system and method for codebook-based data encoding with temporal pattern recognition. Portions of the data are encoded by different encoding libraries, depending on which library provides the greatest compaction for a given portion of the data. This methodology not only provides substantial improvements in data compaction over use of a single data compaction algorithm with the highest average compaction, but provides substantial additional security in that multiple decoding libraries must be used to decode the data. In some embodiments, each portion of data may further be encoded using different sourceblock sizes, providing further security enhancements as decoding requires multiple decoding libraries and knowledge of the sourceblock size used for each portion of the data. In some embodiments, encoding libraries may be randomly or pseudo-randomly rotated to provide additional security.

Data encoded using multiple codebooks (i.e., encoding/decoding libraries) can provide substantial increased compaction performance compared with using a single codebook, even where the single codebook provides the best average compaction of a plurality of codebooks. The methodology described herein improves data compaction by compacting different portions of data using different codebooks, depending on which codebook provides the greatest compaction for a given portion of data.

In some embodiments, for each sourcepacket of a data set arriving at the encoder, the encoder encodes each sourcepacket using a selection of different codebooks and chooses the codebooks with the highest compaction for the sourcepacket, thus maximizing compaction of the data set as a whole. This approach yields higher compaction rates than using a single codebook, since each sourceblock is compacted according to the codebook giving the highest compaction rate, and not according to an average compaction rate of a single codebook. In some embodiments, the combination of codebooks used may combined together as a new codebook. In other embodiments, the combination of codebooks may be left as separate codebooks, but the codebooks used for encoding of each sourcebook are recorded. Not only does this method maximize compaction of a data set, but also increases security of the data set by in proportion to the number of codebooks used in compaction of the data set, as multiple codebooks would be required to decode each data set.

In some embodiments, each sourcepacket of a data set arriving at the encoder is encoded using a different sourceblock length. Changing the sourceblock length changes the encoding output of a given codebook. Two sourcepackets encoded with the same codebook but using different sourceblock lengths would produce different encoded outputs. Therefore, changing the sourceblock length of some or all sourcepackets in a data set provides additional security. Even if the codebook was known, the sourceblock length would have to be known or derived for each sourceblock in order to decode the data set. Changing the sourceblock length may be used in conjunction with the use of multiple codebooks.

In some embodiments, additional security may be provided by rotating or shuffling codebooks according to a rotation list or according to a random or pseudo-random shuffling function. In one embodiment, prior to transmission, the endpoints (users or devices) of a transmission agree in advance about the rotation list or shuffling function to be used, along with any necessary input parameters such as a list order, function code, cryptographic key, or other indicator, depending on the requirements of the type of list or function being used. Once the rotation list or shuffling function is agreed, the endpoints can encode and decode transmissions from one another using the encodings set forth in the current codebook in the rotation or shuffle plus any necessary input parameters. In some embodiments, the shuffling function may be restricted to permutations within a set of codewords of a given length.

Some non-limiting functions that may be used for shuffling include: 1. given a function f(n) which returns a codebook according to an input parameter n in the range 1 to N are, and given t the number of the current sourcepacket or sourceblock: f(t*M modulo p), where M is an arbitrary multiplying factor (1<=M<=p−1) which acts as a key, and p is a large prime number less than or equal to N; 2. f(A\hat{ }t modulo p), where A is a base relatively prime to p−1 which acts as a key, and p is a large prime number less than or equal to N; 3. f (floor(t*x) modulo N), and x is an irrational number chosen randomly to act as a key; 4. f (t XOR K) where the XOR is performed bit-wise on the binary representations of t and a key K with same number of bits in its representation of N. The function f (n) may return the nth codebook simply by referencing the nth element in a list of codebooks, or it could return the nth codebook given by a formula chosen by a user.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to usage in the one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only, and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and in order to more fully illustrate one or more aspects. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Definitions

The term “bit” refers to the smallest unit of information that can be stored or transmitted. It is in the form of a binary digit (either 0 or 1). In terms of hardware, the bit is represented as an electrical signal that is either off (representing 0) or on (representing 1).

The term “byte” refers to a series of bits exactly eight bits in length.

The term “codebook” refers to a database containing sourceblocks each with a pattern of bits and reference code unique within that library. The terms “library” and “encoding/decoding library” are synonymous with the term codebook.

The terms “compression” and “deflation” as used herein mean the representation of data in a more compact form than the original dataset. Compression and/or deflation may be either “lossless”, in which the data can be reconstructed in its original form without any loss of the original data, or “lossy” in which the data can be reconstructed in its original form, but with some loss of the original data.

The terms “compression factor” and “deflation factor” as used herein mean the net reduction in size of the compressed data relative to the original data (e.g., if the new data is 70% of the size of the original, then the deflation/compression factor is 30% or 0.3.)

The terms “compression ratio” and “deflation ratio”, and as used herein all mean the size of the original data relative to the size of the compressed data (e.g., if the new data is 70% of the size of the original, then the deflation/compression ratio is 70% or 0.7.)

The term “data” means information in any computer-readable form.

The term “data set” refers to a grouping of data for a particular purpose. One example of a data set might be a word processing file containing text and formatting information.

The term “effective compression” or “effective compression ratio” refers to the additional amount data that can be stored using the method herein described versus conventional data storage methods. Although the method herein described is not data compression, per se, expressing the additional capacity in terms of compression is a useful comparison.

The term “sourcepacket” as used herein means a packet of data received for encoding or decoding. A sourcepacket may be a portion of a data set.

The term “sourceblock” as used herein means a defined number of bits or bytes used as the block size for encoding or decoding. A sourcepacket may be divisible into a number of sourceblocks. As one non-limiting example, a 1 megabyte sourcepacket of data may be encoded using 512 byte sourceblocks. The number of bits in a sourceblock may be dynamically optimized by the system during operation. In one aspect, a sourceblock may be of the same length as the block size used by a particular file system, typically 512 bytes or 4,096 bytes.

The term “codeword” refers to the reference code form in which data is stored or transmitted in an aspect of the system. A codeword consists of a reference code to a sourceblock in the library plus an indication of that sourceblock's location in a particular data set.

### Conceptual Architecture

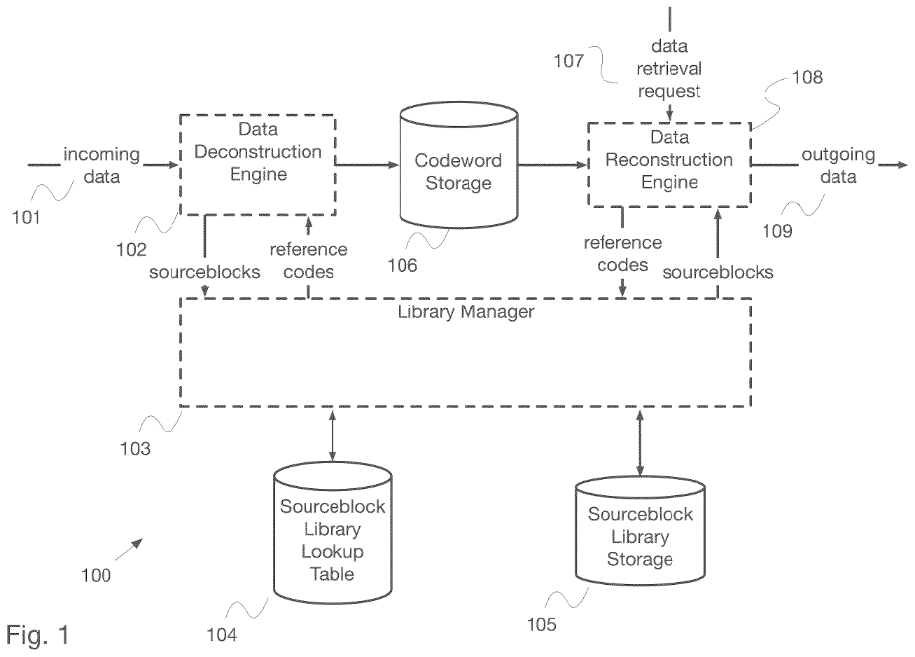

FIG. 1 is a diagram showing an embodiment 100 of the system in which all components of the system are operated locally. As incoming data 101 is received by data deconstruction engine 102. Data deconstruction engine 102 breaks the incoming data into sourceblocks, which are then sent to library manager 103. Using the information contained in sourceblock library lookup table 104 and sourceblock library storage 105, library manager 103 returns reference codes to data deconstruction engine 102 for processing into codewords, which are stored in codeword storage 106. When a data retrieval request 107 is received, data reconstruction engine 108 obtains the codewords associated with the data from codeword storage 106, and sends them to library manager 103. Library manager 103 returns the appropriate sourceblocks to data reconstruction engine 108, which assembles them into the proper order and sends out the data in its original form 109.

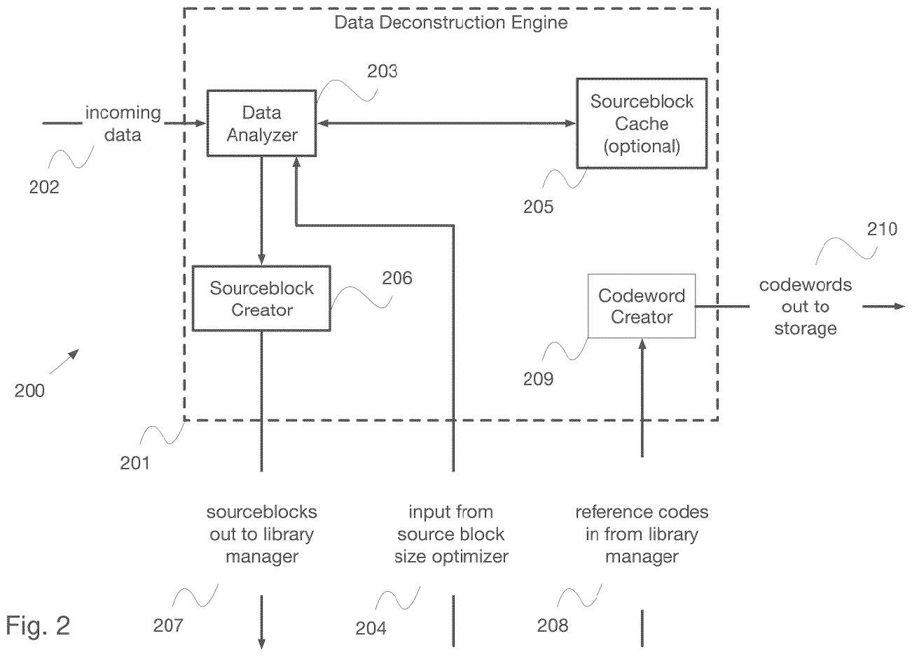

FIG. 2 is a diagram showing an embodiment of one aspect 200 of the system, specifically data deconstruction engine 201. Incoming data 202 is received by data analyzer 203, which optimally analyzes the data based on machine learning algorithms and input 204 from a sourceblock size optimizer, which is disclosed below. Data analyzer may optionally have access to a sourceblock cache 205 of recently-processed sourceblocks, which can increase the speed of the system by avoiding processing in library manager 103. Based on information from data analyzer 203, the data is broken into sourceblocks by sourceblock creator 206, which sends sourceblocks 207 to library manager 203 for additional processing. Data deconstruction engine 201 receives reference codes 208 from library manager 103, corresponding to the sourceblocks in the library that match the sourceblocks sent by sourceblock creator 206, and codeword creator 209 processes the reference codes into codewords comprising a reference code to a sourceblock and a location of that sourceblock within the data set. The original data may be discarded, and the codewords representing the data are sent out to storage 210.

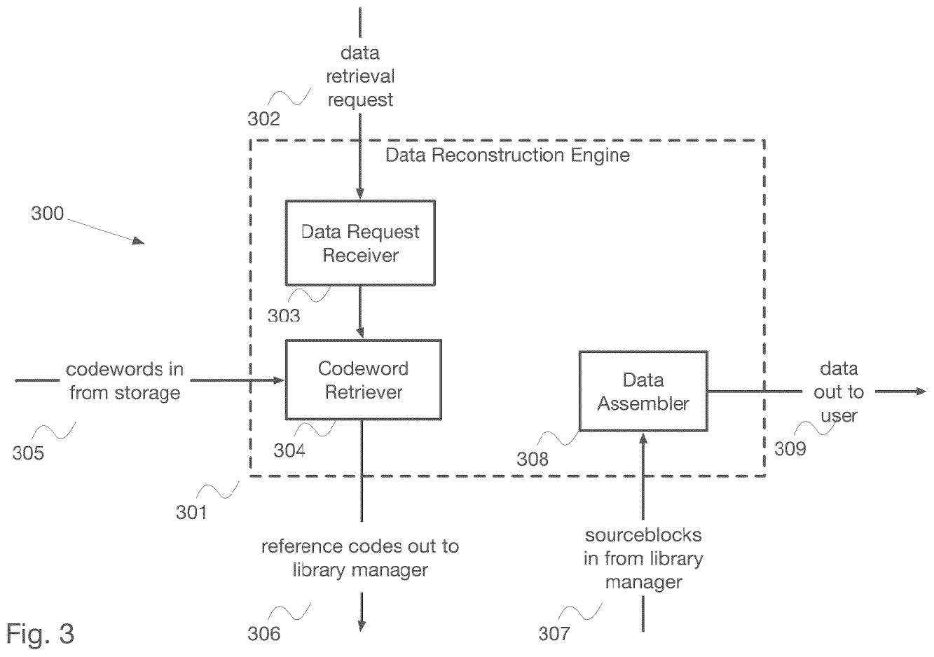

FIG. 3 is a diagram showing an embodiment of another aspect of system 300, specifically data reconstruction engine 301. When a data retrieval request 302 is received by data request receiver 303 (in the form of a plurality of codewords corresponding to a desired final data set), it passes the information to data retriever 304, which obtains the requested data 305 from storage. Data retriever 304 sends, for each codeword received, a reference codes from the codeword 306 to library manager 103 for retrieval of the specific sourceblock associated with the reference code. Data assembler 308 receives the sourceblock 307 from library manager 103 and, after receiving a plurality of sourceblocks corresponding to a plurality of codewords, assembles them into the proper order based on the location information contained in each codeword (recall each codeword comprises a sourceblock reference code and a location identifier that specifies where in the resulting data set the specific sourceblock should be restored to. The requested data is then sent to user 309 in its original form.

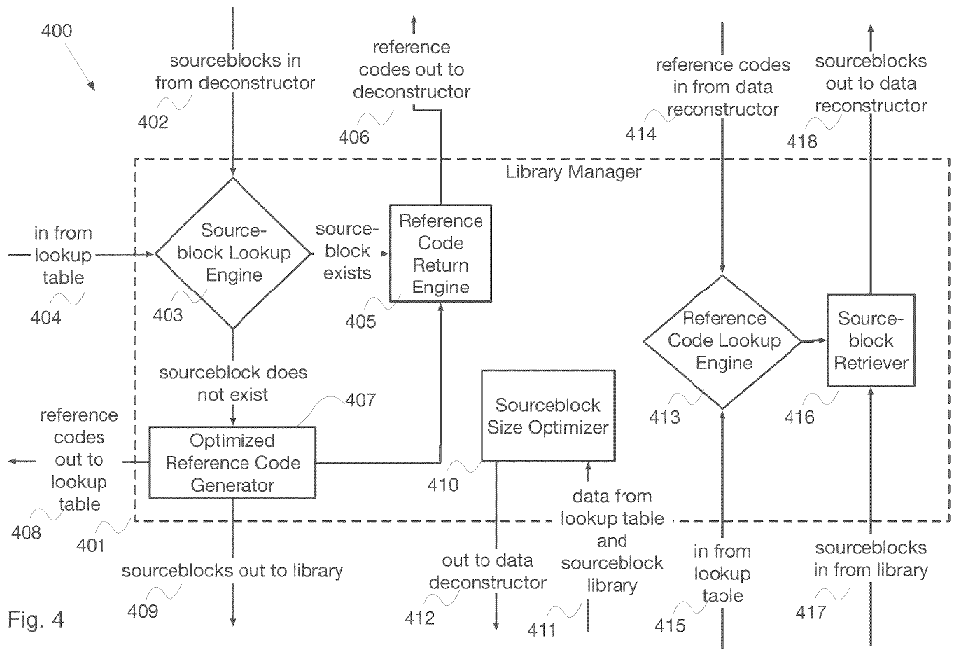

FIG. 4 is a diagram showing an embodiment of another aspect of the system 400, specifically library manager 401. One function of library manager 401 is to generate reference codes from sourceblocks received from data deconstruction engine 301. As sourceblocks are received 402 from data deconstruction engine 301, sourceblock lookup engine 403 checks sourceblock library lookup table 404 to determine whether those sourceblocks already exist in sourceblock library storage 105. If a particular sourceblock exists in sourceblock library storage 105, reference code return engine 405 sends the appropriate reference code 406 to data deconstruction engine 301. If the sourceblock does not exist in sourceblock library storage 105, optimized reference code generator 407 generates a new, optimized reference code based on machine learning algorithms. Optimized reference code generator 407 then saves the reference code 408 to sourceblock library lookup table 104; saves the associated sourceblock 409 to sourceblock library storage 105; and passes the reference code to reference code return engine 405 for sending 406 to data deconstruction engine 301. Another function of library manager 401 is to optimize the size of sourceblocks in the system. Based on information 411 contained in sourceblock library lookup table 104, sourceblock size optimizer 410 dynamically adjusts the size of sourceblocks in the system based on machine learning algorithms and outputs that information 412 to data analyzer 203. Another function of library manager 401 is to return sourceblocks associated with reference codes received from data reconstruction engine 301. As reference codes are received 414 from data reconstruction engine 301, reference code lookup engine 413 checks sourceblock library lookup table 415 to identify the associated sourceblocks; passes that information to sourceblock retriever 416, which obtains the sourceblocks 417 from sourceblock library storage 105; and passes them 418 to data reconstruction engine 301.

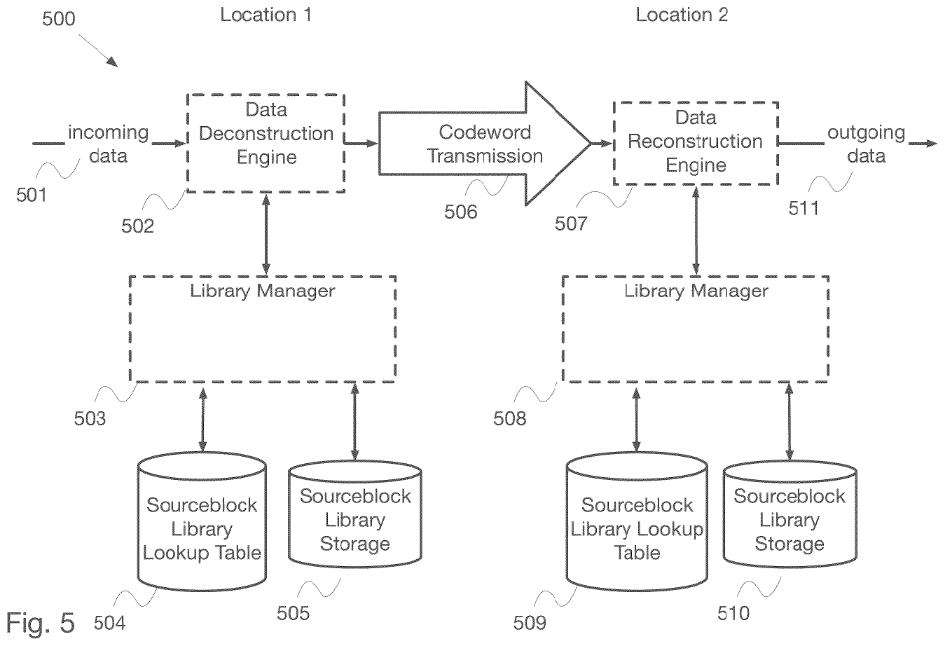

FIG. 5 is a diagram showing another embodiment of system 500, in which data is transferred between remote locations. As incoming data 501 is received by data deconstruction engine 502 at Location 1, data deconstruction engine 301 breaks the incoming data into sourceblocks, which are then sent to library manager 503 at Location 1. Using the information contained in sourceblock library lookup table 504 at Location 1 and sourceblock library storage 505 at Location 1, library manager 503 returns reference codes to data deconstruction engine 301 for processing into codewords, which are transmitted 506 to data reconstruction engine 507 at Location 2. In the case where the reference codes contained in a particular codeword have been newly generated by library manager 503 at Location 1, the codeword is transmitted along with a copy of the associated sourceblock. As data reconstruction engine 507 at Location 2 receives the codewords, it passes them to library manager module 508 at Location 2, which looks up the sourceblock in sourceblock library lookup table 509 at Location 2, and retrieves the associated from sourceblock library storage 510. Where a sourceblock has been transmitted along with a codeword, the sourceblock is stored in sourceblock library storage 510 and sourceblock library lookup table 504 is updated. Library manager 503 returns the appropriate sourceblocks to data reconstruction engine 507, which assembles them into the proper order and sends the data in its original form 511.

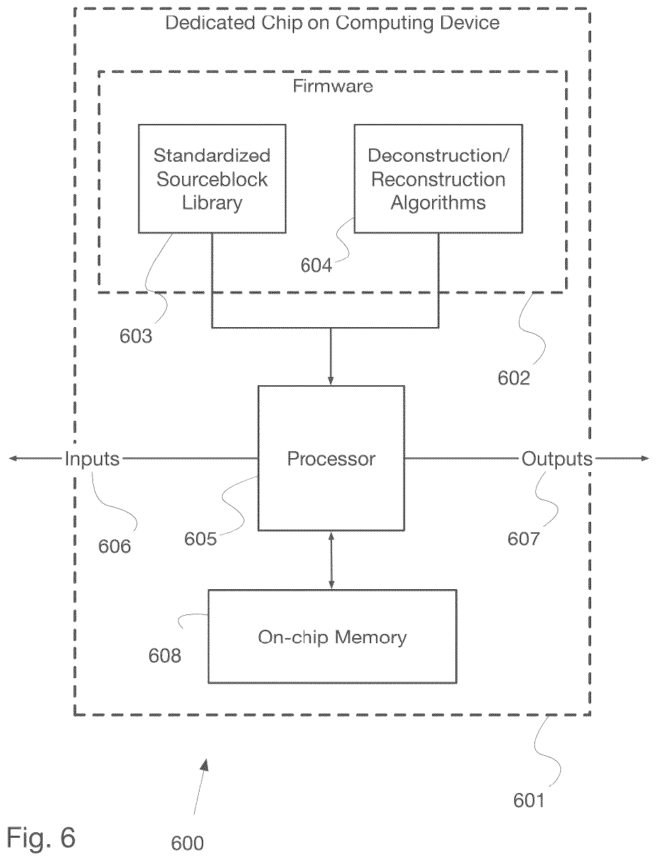

FIG. 6 is a diagram showing an embodiment 600 in which a standardized version of a sourceblock library 603 and associated algorithms 604 would be encoded as firmware 602 on a dedicated processing chip 601 included as part of the hardware of a plurality of devices 600. Contained on dedicated chip 601 would be a firmware area 602, on which would be stored a copy of a standardized sourceblock library 603 and deconstruction/reconstruction algorithms 604 for processing the data. Processor 605 would have both inputs 606 and outputs 607 to other hardware on the device 600. Processor 605 would store incoming data for processing on on-chip memory 608, process the data using standardized sourceblock library 603 and deconstruction/reconstruction algorithms 604, and send the processed data to other hardware on device 600. Using this embodiment, the encoding and decoding of data would be handled by dedicated chip 601, keeping the burden of data processing off device's 600 primary processors. Any device equipped with this embodiment would be able to store and transmit data in a highly optimized, bandwidth-efficient format with any other device equipped with this embodiment.

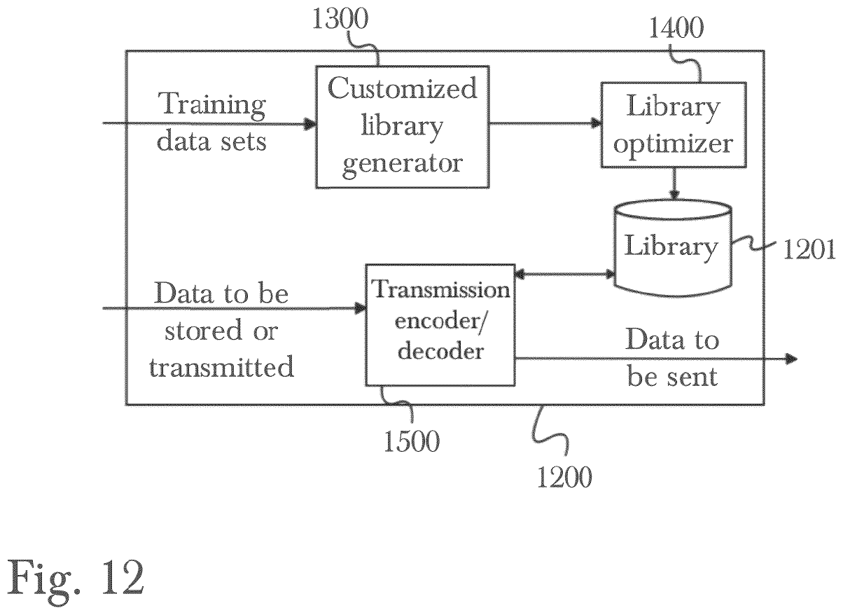

FIG. 12 is a diagram showing an exemplary system architecture 1200, according to a preferred embodiment of the invention. Incoming training data sets may be received at a customized library generator 1300 that processes training data to produce a customized word library 1201 comprising key-value pairs of data words (each comprising a string of bits) and their corresponding calculated binary Huffman codewords. The resultant word library 1201 may then be processed by a library optimizer 1400 to reduce size and improve efficiency, for example by pruning low-occurrence data entries or calculating approximate codewords that may be used to match more than one data word. A transmission encoder/decoder 1500 may be used to receive incoming data intended for storage or transmission, process the data using a word library 1201 to retrieve codewords for the words in the incoming data, and then append the codewords (rather than the original data) to an outbound data stream. Each of these components is described in greater detail below, illustrating the particulars of their respective processing and other functions, referring to FIGS. 2-4.

System 1200 provides near-instantaneous source coding that is dictionary-based and learned in advance from sample training data, so that encoding and decoding may happen concurrently with data transmission. This results in computational latency that is near zero but the data size reduction is comparable to classical compression. For example, if N bits are to be transmitted from sender to receiver, the compression ratio of classical compression is C, the ratio between the deflation factor of system 1200 and that of multi-pass source coding is p, the classical compression encoding rate is R_{C} bit/s and the decoding rate is R_{D} bit/s, and the transmission speed is S bit/s, the compress-send-decompress time will be

$${T}_{old} = \frac{N}{{R}_{C}} + \frac{N}{CS} + \frac{N}{{CR}_{D}}$$

while the transmit-while-coding time for system 1200 will be (assuming that encoding and decoding happen at least as quickly as network latency):

$${T}_{new} = \frac{{N}_{p}}{CS}$$

so that the total data transit time improvement factor is

$$\frac{{T}_{old}}{{T}_{new}} = \frac{\frac{CS}{{R}_{C}} + 1 + \frac{S}{{R}_{D}}}{p}$$

which presents a savings whenever

$$\frac{CS}{{R}_{C}} + \frac{S}{{R}_{D}} > p - 1.$$

This is a reasonable scenario given that typical values in real-world practice are C=0.32, R_{C}=1.1·10¹², R_{D}=4.2·10¹², S=10¹¹, giving

$$\frac{CS}{{R}_{C}} + \frac{S}{{R}_{D}} = 0.053 … ,$$

such that system 1200 will outperform the total transit time of the best compression technology available as long as its deflation factor is no more than 5% worse than compression. Such customized dictionary-based encoding will also sometimes exceed the deflation ratio of classical compression, particularly when network speeds increase beyond 100 Gb/s.

The delay between data creation and its readiness for use at a receiving end will be equal to only the source word length t (typically 5-15 bytes), divided by the deflation factor C/p and the network speed S, i.e.

$${delay}_{invention} = \frac{tp}{CS}$$

since encoding and decoding occur concurrently with data transmission. On the other hand, the latency associated with classical compression is

$${delay}_{priorart} = \frac{N}{{R}_{C}} + \frac{N}{CS} + \frac{N}{{CR}_{D}}$$

where N is the packet/file size. Even with the generous values chosen above as well as N=512K, t=10, and p=1.05, this results in delayᵢₙᵥₑₙₜᵢₒₙ≈3.3·10⁻¹⁰ while delayₚᵣᵢₒᵣₐᵣₜ≈1.3·10⁻⁷, a more than 400-fold reduction in latency.

A key factor in the efficiency of Huffman coding used by system 1200 is that key-value pairs be chosen carefully to minimize expected coding length, so that the average deflation/compression ratio is minimized. It is possible to achieve the best possible expected code length among all instantaneous codes using Huffman codes if one has access to the exact probability distribution of source words of a given desired length from the random variable generating them. In practice this is impossible, as data is received in a wide variety of formats and the random processes underlying the source data are a mixture of human input, unpredictable (though in principle, deterministic) physical events, and noise. System 1200 addresses this by restriction of data types and density estimation; training data is provided that is representative of the type of data anticipated in “real-world” use of system 1200, which is then used to model the distribution of binary strings in the data in order to build a Huffman code word library 1200.

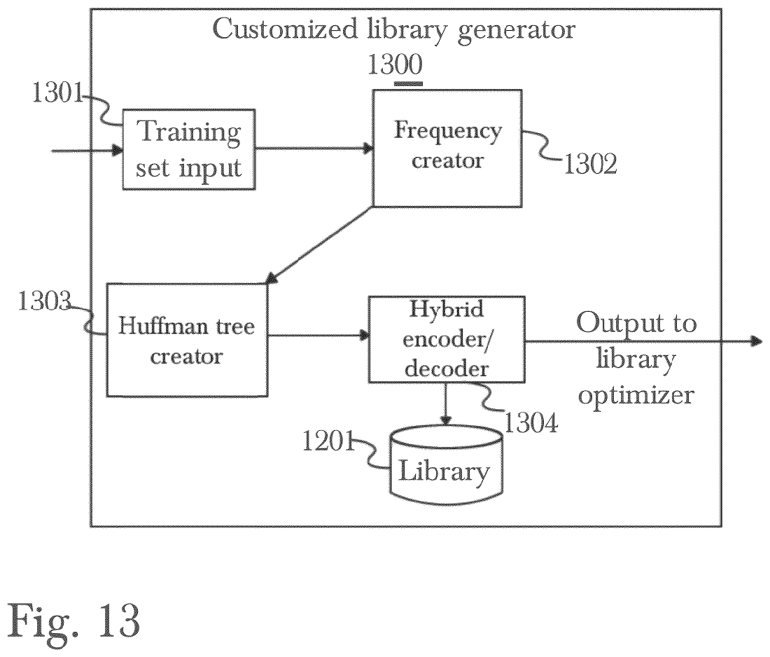

FIG. 13 is a diagram showing a more detailed architecture for a customized library generator 1300. When an incoming training data set 1301 is received, it may be analyzed using a frequency creator 1302 to analyze for word frequency (that is, the frequency with which a given word occurs in the training data set). Word frequency may be analyzed by scanning all substrings of bits and directly calculating the frequency of each substring by iterating over the data set to produce an occurrence frequency, which may then be used to estimate the rate of word occurrence in non-training data. A first Huffman binary tree is created based on the frequency of occurrences of each word in the first dataset, and a Huffman codeword is assigned to each observed word in the first dataset according to the first Huffman binary tree. Machine learning may be utilized to improve results by processing a number of training data sets and using the results of each training set to refine the frequency estimations for non-training data, so that the estimation yield better results when used with real-world data (rather than, for example, being only based on a single training data set that may not be very similar to a received non-training data set). A second Huffman tree creator 1303 may be utilized to identify words that do not match any existing entries in a word library 1201 and pass them to a hybrid encoder/decoder 1304, that then calculates a binary Huffman codeword for the mismatched word and adds the codeword and original data to the word library 1201 as a new key-value pair. In this manner, customized library generator 1300 may be used both to establish an initial word library 1201 from a first training set, as well as expand the word library 1201 using additional training data to improve operation.

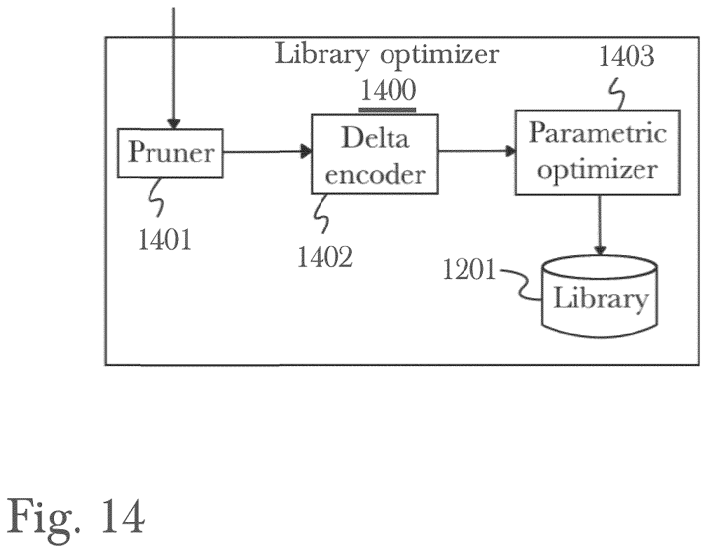

FIG. 14 is a diagram showing a more detailed architecture for a library optimizer 1400. A pruner 1401 may be used to load a word library 1201 and reduce its size for efficient operation, for example by sorting the word library 1201 based on the known occurrence probability of each key-value pair and removing low-probability key-value pairs based on a loaded threshold parameter. This prunes low-value data from the word library to trim the size, eliminating large quantities of very-low-frequency key-value pairs such as single-occurrence words that are unlikely to be encountered again in a data set. Pruning eliminates the least-probable entries from word library 1201 up to a given threshold, which will have a negligible impact on the deflation factor since the removed entries are only the least-common ones, while the impact on word library size will be larger because samples drawn from asymptotically normal distributions (such as the log-probabilities of words generated by a probabilistic finite state machine, a model well-suited to a wide variety of real-world data) which occur in tails of the distribution are disproportionately large in counting measure. A delta encoder 1402 may be utilized to apply delta encoding to a plurality of words to store an approximate codeword as a value in the word library, for which each of the plurality of source words is a valid corresponding key. This may be used to reduce library size by replacing numerous key-value pairs with a single entry for the approximate codeword and then represent actual codewords using the approximate codeword plus a delta value representing the difference between the approximate codeword and the actual codeword. Approximate coding is optimized for low-weight sources such as Golomb coding, run-length coding, and similar techniques. The approximate source words may be chosen by locality-sensitive hashing, so as to approximate Hamming distance without incurring the intractability of nearest-neighbor-search in Hamming space. A parametric optimizer 1403 may load configuration parameters for operation to optimize the use of the word library 1201 during operation. Best-practice parameter/hyperparameter optimization strategies such as stochastic gradient descent, quasi-random grid search, and evolutionary search may be used to make optimal choices for all interdependent settings playing a role in the functionality of system 1200. In cases where lossless compression is not required, the delta value may be discarded at the expense of introducing some limited errors into any decoded (reconstructed) data.

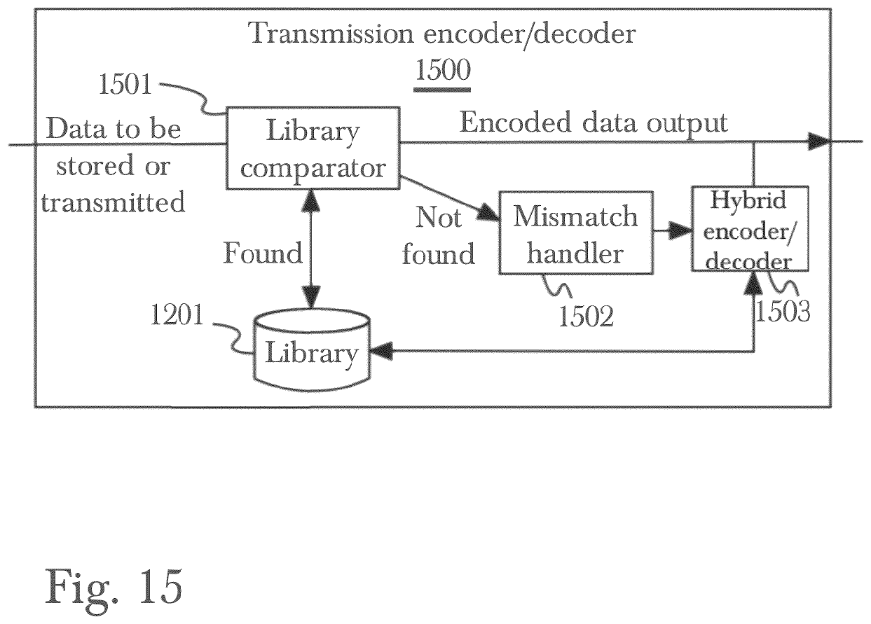

FIG. 15 is a diagram showing a more detailed architecture for a transmission encoder/decoder 1500. According to various arrangements, transmission encoder/decoder 1500 may be used to deconstruct data for storage or transmission, or to reconstruct data that has been received, using a word library 1201. A library comparator 1501 may be used to receive data comprising words or codewords, and compare against a word library 1201 by dividing the incoming stream into substrings of length t and using a fast hash to check word library 1201 for each substring. If a substring is found in word library 1201, the corresponding key/value (that is, the corresponding source word or codeword, according to whether the substring used in comparison was itself a word or codeword) is returned and appended to an output stream. If a given substring is not found in word library 1201, a mismatch handler 1502 and hybrid encoder/decoder 1503 may be used to handle the mismatch similarly to operation during the construction or expansion of word library 1201. A mismatch handler 1502 may be utilized to identify words that do not match any existing entries in a word library 1201 and pass them to a hybrid encoder/decoder 1503, that then calculates a binary Huffman codeword for the mismatched word and adds the codeword and original data to the word library 1201 as a new key-value pair. The newly-produced codeword may then be appended to the output stream. In arrangements where a mismatch indicator is included in a received data stream, this may be used to preemptively identify a substring that is not in word library 1201 (for example, if it was identified as a mismatch on the transmission end), and handled accordingly without the need for a library lookup.

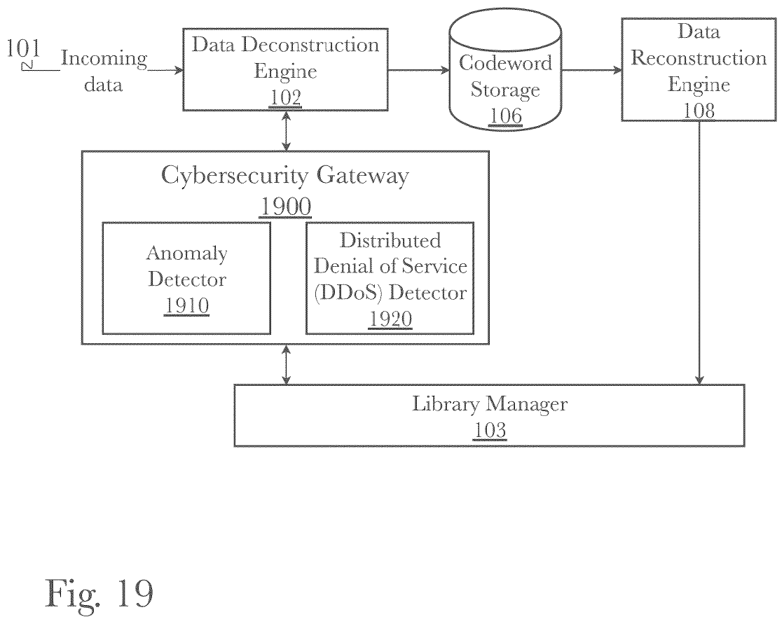

FIG. 19 is an exemplary system architecture of a data encoding system used for cyber security purposes. Much like in FIG. 1, incoming data 101 to be deconstructed is sent to a data deconstruction engine 102, which may attempt to deconstruct the data and turn it into a collection of codewords using a library manager 103. Codeword storage 106 serves to store unique codewords from this process, and may be queried by a data reconstruction engine 108 which may reconstruct the original data from the codewords, using a library manager 103. However, a cybersecurity gateway 1900 is present, communicating in-between a library manager 103 and a deconstruction engine 102, and containing an anomaly detector 1910 and distributed denial of service (DDoS) detector 1920. The anomaly detector examines incoming data to determine whether there is a disproportionate number of incoming reference codes that do not match reference codes in the existing library. A disproportionate number of non-matching reference codes may indicate that data is being received from an unknown source, of an unknown type, or contains unexpected (possibly malicious) data. If the disproportionate number of non-matching reference codes exceeds an established threshold or persists for a certain length of time, the anomaly detector 1910 raises a warning to a system administrator. Likewise, the DDOS detector 1920 examines incoming data to determine whether there is a disproportionate amount of repetitive data. A disproportionate amount of repetitive data may indicate that a DDOS attack is in progress. If the disproportionate amount of repetitive data exceeds an established threshold or persists for a certain length of time, the DDOS detector 1910 raises a warning to a system administrator. In this way, a data encoding system may detect and warn users of, or help mitigate, common cyber-attacks that result from a flow of unexpected and potentially harmful data, or attacks that result from a flow of too much irrelevant data meant to slow down a network or system, as in the case of a DDOS attack.

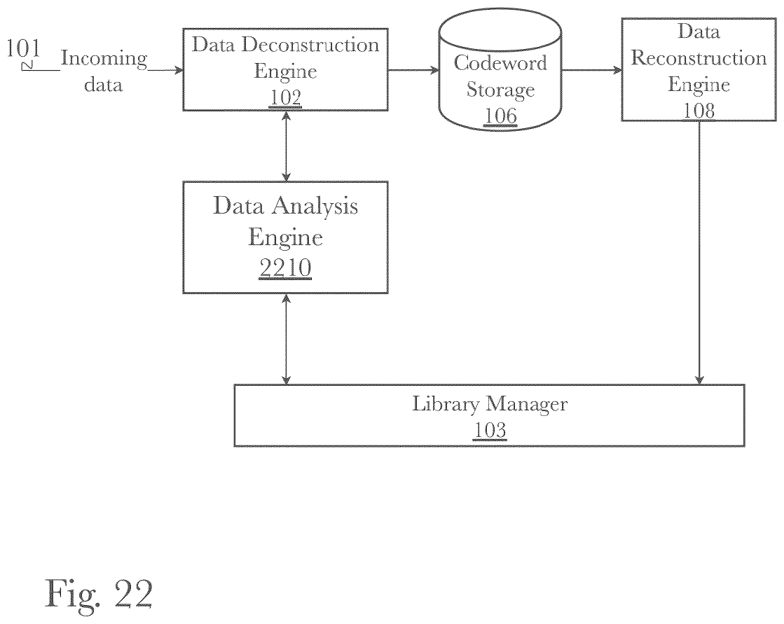

FIG. 22 is an exemplary system architecture of a data encoding system used for data mining and analysis purposes. Much like in FIG. 1, incoming data 101 to be deconstructed is sent to a data deconstruction engine 102, which may attempt to deconstruct the data and turn it into a collection of codewords using a library manager 103. Codeword storage 106 serves to store unique codewords from this process, and may be queried by a data reconstruction engine 108 which may reconstruct the original data from the codewords, using a library manager 103. A data analysis engine 2210, typically operating while the system is otherwise idle, sends requests for data to the data reconstruction engine 108, which retrieves the codewords representing the requested data from codeword storage 106, reconstructs them into the data represented by the codewords, and send the reconstructed data to the data analysis engine 2210 for analysis and extraction of useful data (i.e., data mining). Because the speed of reconstruction is significantly faster than decompression using traditional compression technologies (i.e., significantly less decompression latency), this approach makes data mining feasible. Very often, data stored using traditional compression is not mined precisely because decompression lag makes it unfeasible, especially during shorter periods of system idleness. Increasing the speed of data reconstruction broadens the circumstances under which data mining of stored data is feasible.

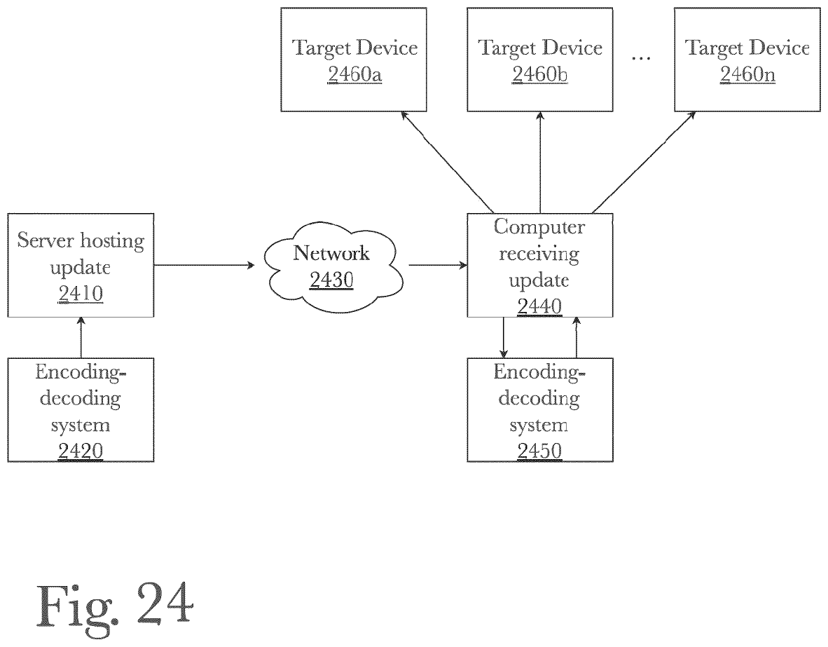

FIG. 24 is an exemplary system architecture of a data encoding system used for remote software and firmware updates. Software and firmware updates typically require smaller, but more frequent, file transfers. A server which hosts a software or firmware update 2410 may host an encoding-decoding system 2420, allowing for data to be encoded into, and decoded from, sourceblocks or codewords, as disclosed in previous figures. Such a server may possess a software update, operating system update, firmware update, device driver update, or any other form of software update, which in some cases may be minor changes to a file, but nevertheless necessitate sending the new, completed file to the recipient. Such a server is connected over a network 2430, which is further connected to a recipient computer 2440, which may be connected to a server 2410 for receiving such an update to its system. In this instance, the recipient device 2440 also hosts the encoding and decoding system 2450, along with a codebook or library of reference codes that the hosting server 2410 also shares. The updates are retrieved from storage at the hosting server 2410 in the form of codewords, transferred over the network 2430 in the form of codewords, and reconstructed on the receiving computer 2440. In this way, a far smaller file size, and smaller total update size, may be sent over a network. The receiving computer 2440 may then install the updates on any number of target computing devices 2460a-n, using a local network or other high-bandwidth connection.

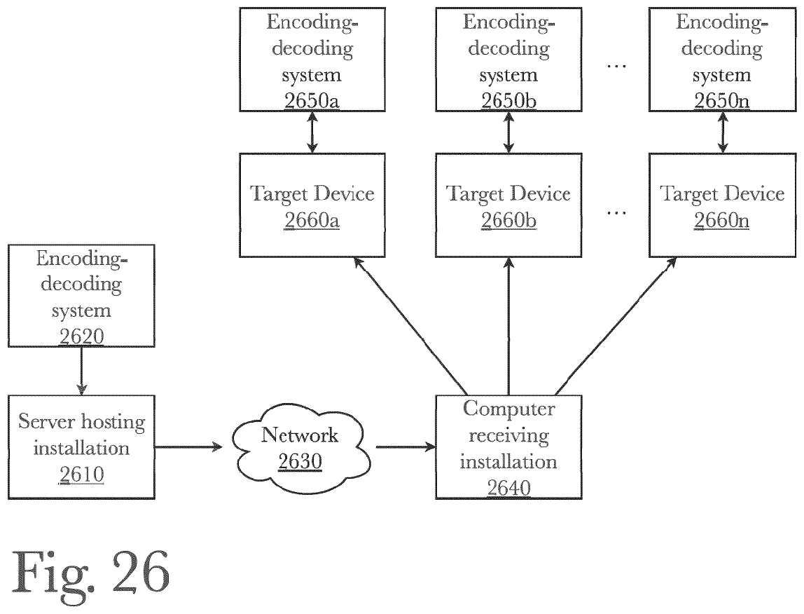

FIG. 26 is an exemplary system architecture of a data encoding system used for large-scale software installation such as operating systems. Large-scale software installations typically require very large, but infrequent, file transfers. A server which hosts an installable software 2610 may host an encoding-decoding system 2620, allowing for data to be encoded into, and decoded from, sourceblocks or codewords, as disclosed in previous figures. The files for the large scale software installation are hosted on the server 2610, which is connected over a network 2630 to a recipient computer 2640. In this instance, the encoding and decoding system 2650a-n is stored on or connected to one or more target devices 2660a-n, along with a codebook or library of reference codes that the hosting server 2610 shares. The software is retrieved from storage at the hosting server 2610 in the form of codewords and transferred over the network 2630 in the form of codewords to the receiving computer 2640. However, instead of being reconstructed at the receiving computer 2640, the codewords are transmitted to one or more target computing devices, and reconstructed and installed directly on the target devices 2660a-n. In this way, a far smaller file size, and smaller total update size, may be sent over a network or transferred between computing devices, even where the network 2630 between the receiving computer 2640 and target devices 2660a-n is low bandwidth, or where there are many target devices 2660a-n.

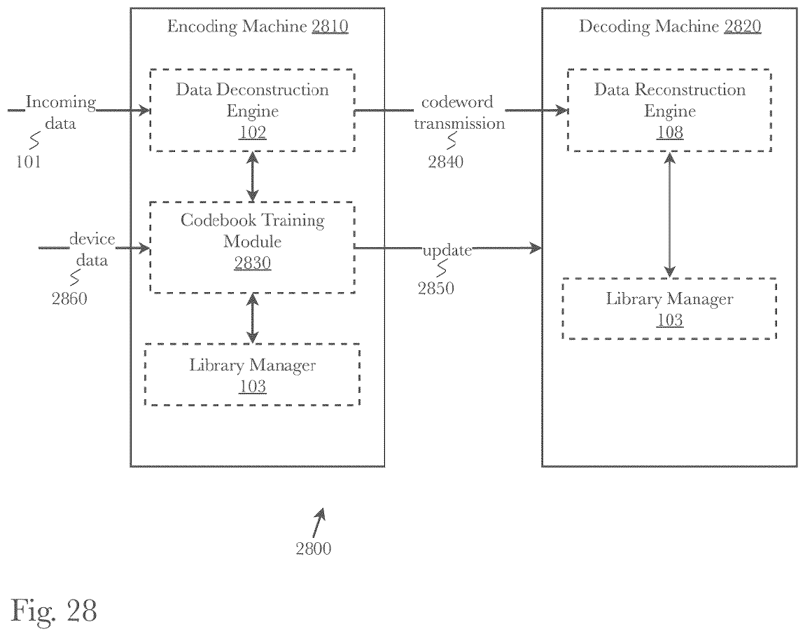

FIG. 28 is a block diagram of an exemplary system architecture 2800 of a codebook training system for a data encoding system, according to an embodiment. According to this embodiment, two separate machines may be used for encoding 2810 and decoding 2820. Much like in FIG. 1, incoming data 101 to be deconstructed is sent to a data deconstruction engine 102 residing on encoding machine 2810, which may attempt to deconstruct the data and turn it into a collection of codewords using a library manager 103. Codewords may be transmitted 2840 to a data reconstruction engine 108 residing on decoding machine 2820, which may reconstruct the original data from the codewords, using a library manager 103. However, according to this embodiment, a codebook training module 2830 is present on the decoding machine 2810, communicating in-between a library manager 103 and a deconstruction engine 102. According to other embodiments, codebook training module 2830 may reside instead on decoding machine 2820 if the machine has enough computing resources available; which machine the module 2830 is located on may depend on the system user's architecture and network structure. Codebook training module 2830 may send requests for data to the data reconstruction engine 2810, which routes incoming data 101 to codebook training module 2830. Codebook training module 2830 may perform analyses on the requested data in order to gather information about the distribution of incoming data 101 as well as monitor the encoding/decoding model performance. Additionally, codebook training module 2830 may also request and receive device data 2860 to supervise network connected devices and their processes and, according to some embodiments, to allocate training resources when requested by devices running the encoding system. Devices may include, but are not limited to, encoding and decoding machines, training machines, sensors, mobile computing devices, and Internet-of-things (“IoT”) devices. Based on the results of the analyses, the codebook training module 2830 may create a new training dataset from a subset of the requested data in order to counteract the effects of data drift on the encoding/decoding models, and then publish updated 2850 codebooks to both the encoding machine 2810 and decoding machine 2820.

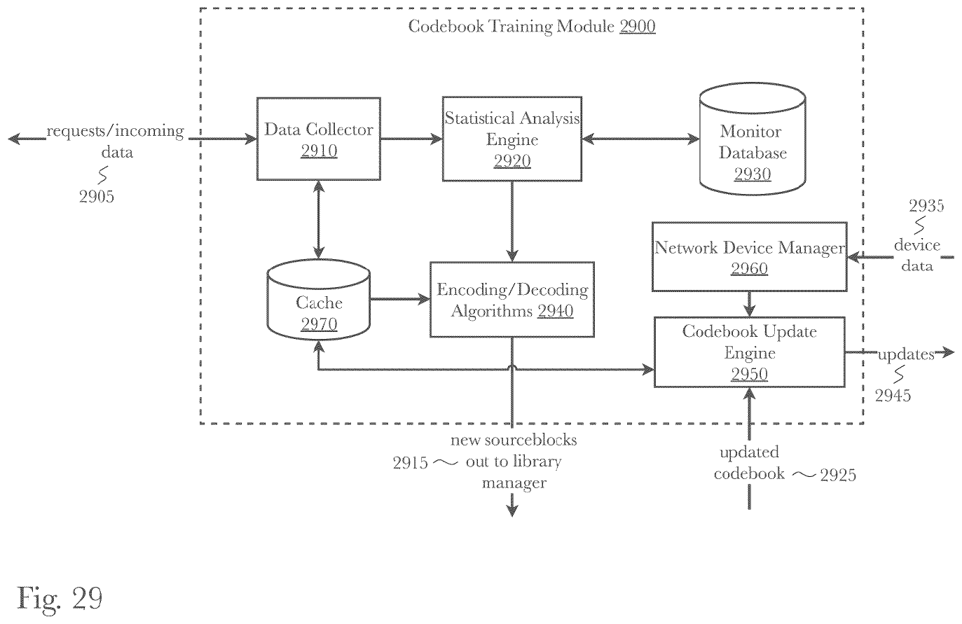

FIG. 29 is a block diagram of an exemplary architecture for a codebook training module 2900, according to an embodiment. According to the embodiment, a data collector 2910 is present which may send requests for incoming data 2905 to a data deconstruction engine 102 which may receive the request and route incoming data to codebook training module 2900 where it may be received by data collector 2910. Data collector 2910 may be configured to request data periodically such as at schedule time intervals, or for example, it may be configured to request data after a certain amount of data has been processed through the encoding machine 2810 or decoding machine 2820. The received data may be a plurality of sourceblocks, which are a series of binary digits, originating from a source packet otherwise referred to as a datagram. The received data may compiled into a test dataset and temporarily stored in a cache 2970. Once stored, the test dataset may be forwarded to a statistical analysis engine 2920 which may utilize one or more algorithms to determine the probability distribution of the test dataset. Best-practice probability distribution algorithms such as Kullback-Leibler divergence, adaptive windowing, and Jensen-Shannon divergence may be used to compute the probability distribution of training and test datasets. A monitoring database 2930 may be used to store a variety of statistical data related to training datasets and model performance metrics in one place to facilitate quick and accurate system monitoring capabilities as well as assist in system debugging functions. For example, the original or current training dataset and the calculated probability distribution of this training dataset used to develop the current encoding and decoding algorithms may be stored in monitor database 2930.

Since data drifts involve statistical change in the data, the best approach to detect drift is by monitoring the incoming data's statistical properties, the model's predictions, and their correlation with other factors. After statistical analysis engine 2920 calculates the probability distribution of the test dataset it may retrieve from monitor database 2930 the calculated and stored probability distribution of the current training dataset. It may then compare the two probability distributions of the two different datasets in order to verify if the difference in calculated distributions exceeds a predetermined difference threshold. If the difference in distributions does not exceed the difference threshold, that indicates the test dataset, and therefore the incoming data, has not experienced enough data drift to cause the encoding/decoding system performance to degrade significantly, which indicates that no updates are necessary to the existing codebooks. However, if the difference threshold has been surpassed, then the data drift is significant enough to cause the encoding/decoding system performance to degrade to the point where the existing models and accompanying codebooks need to be updated. According to an embodiment, an alert may be generated by statistical analysis engine 2920 if the difference threshold is surpassed or if otherwise unexpected behavior arises.

In the event that an update is required, the test dataset stored in the cache 2970 and its associated calculated probability distribution may be sent to monitor database 2930 for long term storage. This test dataset may be used as a new training dataset to retrain the encoding and decoding algorithms 2940 used to create new sourceblocks based upon the changed probability distribution. The new sourceblocks may be sent out to a library manager 2915 where the sourceblocks can be assigned new codewords. Each new sourceblock and its associated codeword may then be added to a new codebook and stored in a storage device. The new and updated codebook may then be sent back 2925 to codebook training module 2900 and received by a codebook update engine 2950. Codebook update engine 2950 may temporarily store the received updated codebook in the cache 2970 until other network devices and machines are ready, at which point codebook update engine 2950 will publish the updated codebooks 2945 to the necessary network devices.

A network device manager 2960 may also be present which may request and receive network device data 2935 from a plurality of network connected devices and machines. When the disclosed encoding system and codebook training system 2800 are deployed in a production environment, upstream process changes may lead to data drift, or other unexpected behavior. For example, a sensor being replaced that changes the units of measurement from inches to centimeters, data quality issues such as a broken sensor always reading 0, and covariate shift which occurs when there is a change in the distribution of input variables from the training set. These sorts of behavior and issues may be determined from the received device data 2935 in order to identify potential causes of system error that is not related to data drift and therefore does not require an updated codebook. This can save network resources from being unnecessarily used on training new algorithms as well as alert system users to malfunctions and unexpected behavior devices connected to their networks. Network device manager 2960 may also utilize device data 2935 to determine available network resources and device downtime or periods of time when device usage is at its lowest. Codebook update engine 2950 may request network and device availability data from network device manager 2960 in order to determine the most optimal time to transmit updated codebooks (i.e., trained libraries) to encoder and decoder devices and machines.

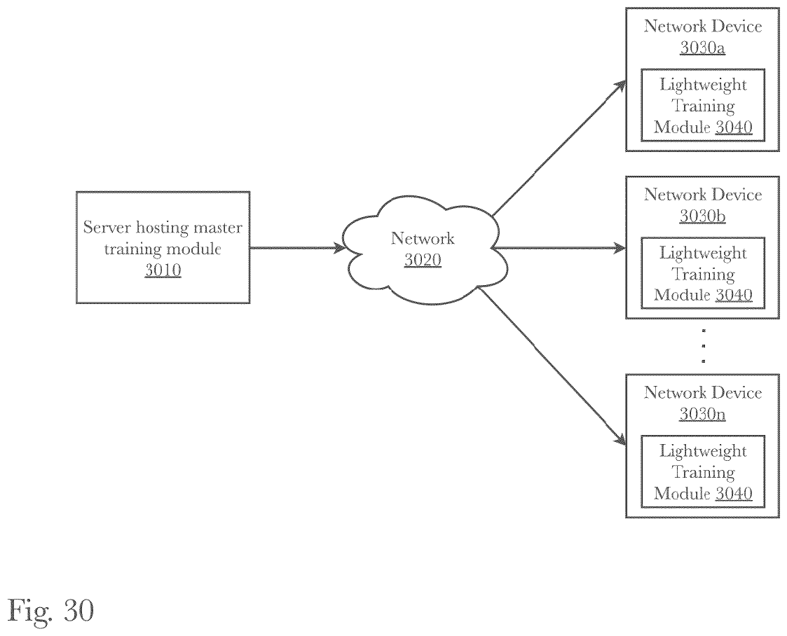

FIG. 30 is a block diagram of another embodiment of the codebook training system using a distributed architecture and a modified training module. According to an embodiment, there may be a server which maintains a master supervisory process over remote training devices hosting a master training module 3010 which communicates via a network 3020 to a plurality of connected network devices 3030a-n. The server may be located at the remote training end such as, but not limited to, cloud-based resources, a user-owned data center, etc. The master training module located on the server operates similarly to the codebook training module disclosed in FIG. 29 above, however, the server 3010 utilizes the master training module via the network device manager 2960 to farm out training resources to network devices 3030a-n. The server 3010 may allocate resources in a variety of ways, for example, round-robin, priority-based, or other manner, depending on the user needs, costs, and number of devices running the encoding/decoding system. Server 3010 may identify elastic resources which can be employed if available to scale up training when the load becomes too burdensome. On the network devices 3030a-n may be present a lightweight version of the training module 3040 that trades a little suboptimality in the codebook for training on limited machinery and/or makes training happen in low-priority threads to take advantage of idle time. In this way the training of new encoding/decoding algorithms may take place in a distributed manner which allows data gathering or generating devices to process and train on data gathered locally, which may improve system latency and optimize available network resources.

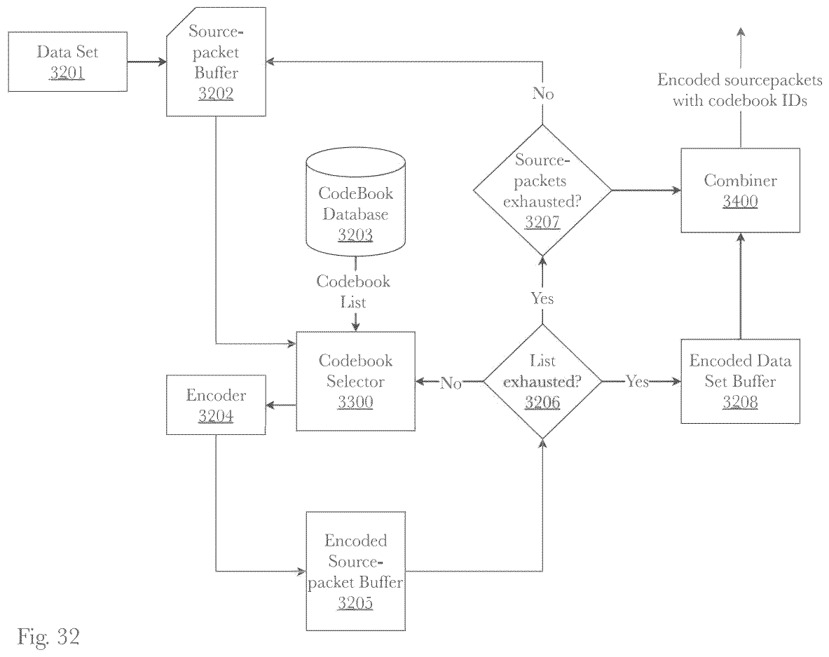

FIG. 32 is an exemplary system architecture for an encoding system with multiple codebooks. A data set to be encoded 3201 is sent to a sourcepacket buffer 3202. The sourcepacket buffer is an array which stores the data which is to be encoded and may contain a plurality of sourcepackets. Each sourcepacket is routed to a codebook selector 3300, which retrieves a list of codebooks from a codebook database 3203. The sourcepacket is encoded using the first codebook on the list via an encoder 3204, and the output is stored in an encoded sourcepacket buffer 3205. The process is repeated with the same sourcepacket using each subsequent codebook on the list until the list of codebooks is exhausted 3206, at which point the most compact encoded version of the sourcepacket is selected from the encoded sourcepacket buffer 3205 and sent to an encoded data set buffer 3208 along with the ID of the codebook used to produce it. The sourcepacket buffer 3202 is determined to be exhausted 3207, a notification is sent to a combiner 3400, which retrieves all of the encoded sourcepackets and codebook IDs from the encoded data set buffer 3208 and combines them into a single file for output.

According to an embodiment, the list of codebooks used in encoding the data set may be consolidated to a single codebook which is provided to the combiner 3400 for output along with the encoded sourcepackets and codebook IDs. In this case, the single codebook will contain the data from, and codebook IDs of, each of the codebooks used to encode the data set. This may provide a reduction in data transfer time, although it is not required since each sourcepacket (or sourceblock) will contain a reference to a specific codebook ID which references a codebook that can be pulled from a database or be sent alongside the encoded data to a receiving device for the decoding process.

In some embodiments, each sourcepacket of a data set 3201 arriving at the encoder 3204 is encoded using a different sourceblock length. Changing the sourceblock length changes the encoding output of a given codebook. Two sourcepackets encoded with the same codebook but using different sourceblock lengths would produce different encoded outputs. Therefore, changing the sourceblock length of some or all sourcepackets in a data set 3201 provides additional security. Even if the codebook was known, the sourceblock length would have to be known or derived for each sourceblock in order to decode the data set 3201. Changing the sourceblock length may be used in conjunction with the use of multiple codebooks.

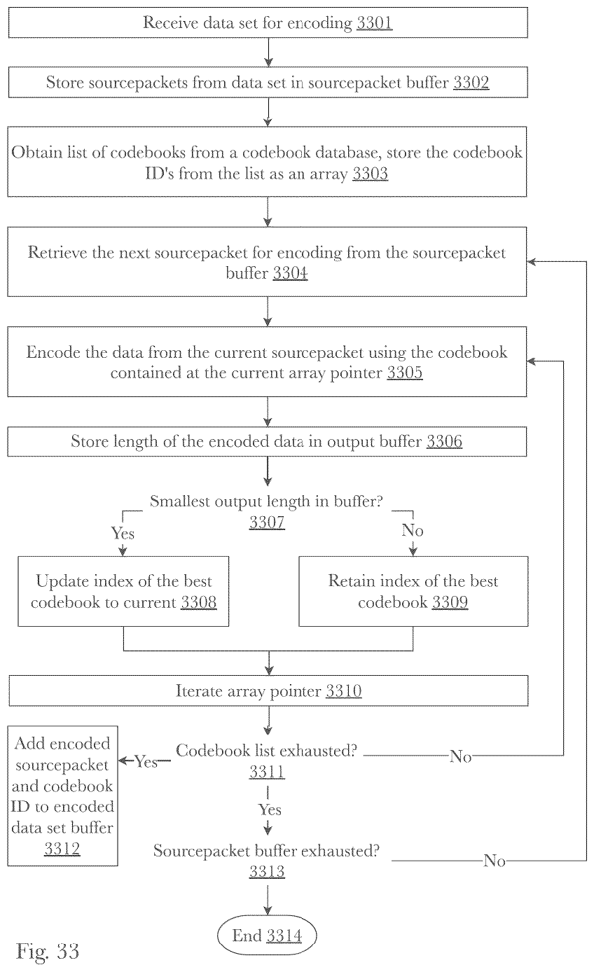

FIG. 33 is a flow diagram describing an exemplary algorithm for encoding of data using multiple codebooks. A data set is received for encoding 3301, the data set comprising a plurality of sourcepackets. The sourcepackets are stored in a sourcepacket buffer 3302. A list of codebooks to be used for multiple codebook encoding is retrieved from a codebook database (which may contain more codebooks than are contained in the list) and the codebook IDs for each codebook on the list are stored as an array 3303. The next sourcepacket in the sourcepacket buffer is retrieved from the sourcepacket buffer for encoding 3304. The sourcepacket is encoded using the codebook in the array indicated by a current array pointer 3305. The encoded sourcepacket and length of the encoded sourcepacket is stored in an encoded sourcepacket buffer 3306. If the length of the most recently stored sourcepacket is the shortest in the buffer 3607, an index in the buffer is updated to indicate that the codebook indicated by the current array pointer is the most efficient codebook in the buffer for that sourcepacket. If the length of the most recently stored sourcepacket is not the shortest in the buffer 3607, the index in the buffer is not updated because a previous codebook used to encode that sourcepacket was more efficient 3309. The current array pointer is iterated to select the next codebook in the list 3310. If the list of codebooks has not been exhausted 3311, the process is repeated for the next codebook in the list, starting at step 3305. If the list of codebooks has been exhausted 3311, the encoded sourcepacket in the encoded sourcepacket buffer (the most compact version) and the codebook ID for the codebook that encoded it are added to an encoded data set buffer 3312 for later combination with other encoded sourcepackets from the same data set. At that point, the sourcepacket buffer is checked to see if any sourcepackets remain to be encoded 3313. If the sourcepacket buffer is not exhausted, the next sourcepacket is retrieved 3304 and the process is repeated starting at step 3304. If the sourcepacket buffer is exhausted 3313, the encoding process ends 3314. In some embodiments, rather than storing the encoded sourcepacket itself in the encoded sourcepacket buffer, a universal unique identification (UUID) is assigned to each encoded sourcepacket, and the UUID is stored in the encoded sourcepacket buffer instead of the entire encoded sourcepacket.

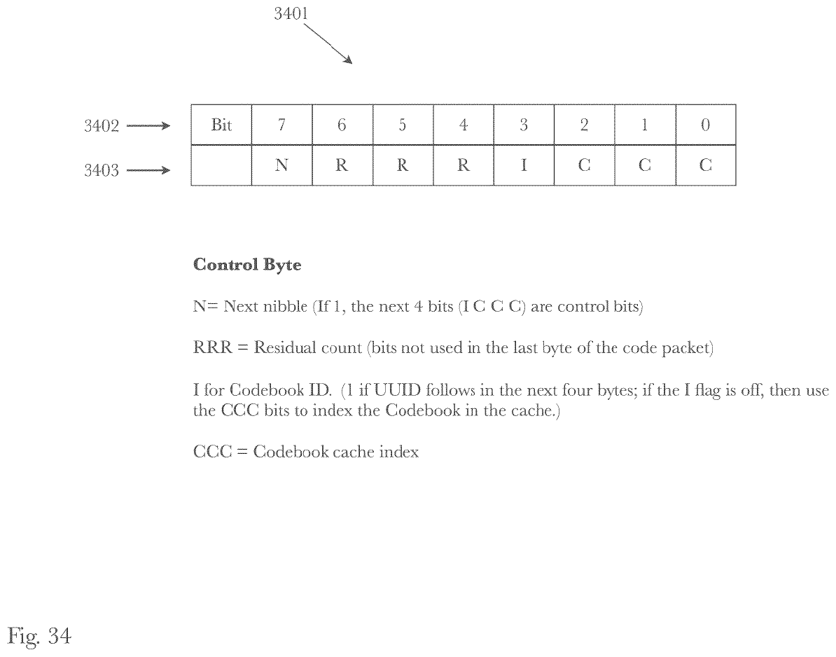

FIG. 34 is a diagram showing an exemplary control byte used to combine sourcepackets encoded with multiple codebooks. In this embodiment, a control byte 3401 (i.e., a series of 8 bits) is inserted at the before (or after, depending on the configuration) the encoded sourcepacket with which it is associated, and provides information about the codebook that was used to encode the sourcepacket. In this way, sourcepackets of a data set encoded using multiple codebooks can be combined into a data structure comprising the encoded sourcepackets, each with a control byte that tells the system how the sourcepacket can be decoded. The data structure may be of numerous forms, but in an embodiment, the data structure comprises a continuous series of control bytes followed by the sourcepacket associated with the control byte. In some embodiments, the data structure will comprise a continuous series of control bytes followed by the UUID of the sourcepacket associated with the control byte (and not the encoded sourcepacket, itself). In some embodiments, the data structure may further comprise a UUID inserted to identify the codebook used to encode the sourcepacket, rather than identifying the codebook in the control byte. Note that, while a very short control code (one byte) is used in this example, the control code may be of any length, and may be considerably longer than one byte in cases where the sourceblocks size is large or in cases where a large number of codebooks have been used to encode the sourcepacket or data set.

In this embodiment, for each bit location 3402 of the control byte 3401, a data bit or combinations of data bits 3403 provide information necessary for decoding of the sourcepacket associated with the control byte. Reading in reverse order of bit locations, the first bit N (location 7) indicates whether the entire control byte is used or not. If a single codebook is used to encode all sourcepackets in the data set, N is set to 0, and bits 3 to 0 of the control byte 3401 are ignored. However, where multiple codebooks are used, N is set to 1 and all 8 bits of the control byte 3401 are used. The next three bits RRR (locations 6 to 4) are a residual count of the number of bits that were not used in the last byte of the sourcepacket. Unused bits in the last byte of a sourcepacket can occur depending on the sourceblock size used to encode the sourcepacket. The next bit I (location 3) is used to identify the codebook used to encode the sourcepacket. If bit I is 0, the next three bits CCC (locations 2 to 0) provide the codebook ID used to encode the sourcepacket. The codebook ID may take the form of a codebook cache index, where the codebooks are stored in an enumerated cache. If bit I is 1, then the codebook is identified using a four-byte UUID that follows the control byte.

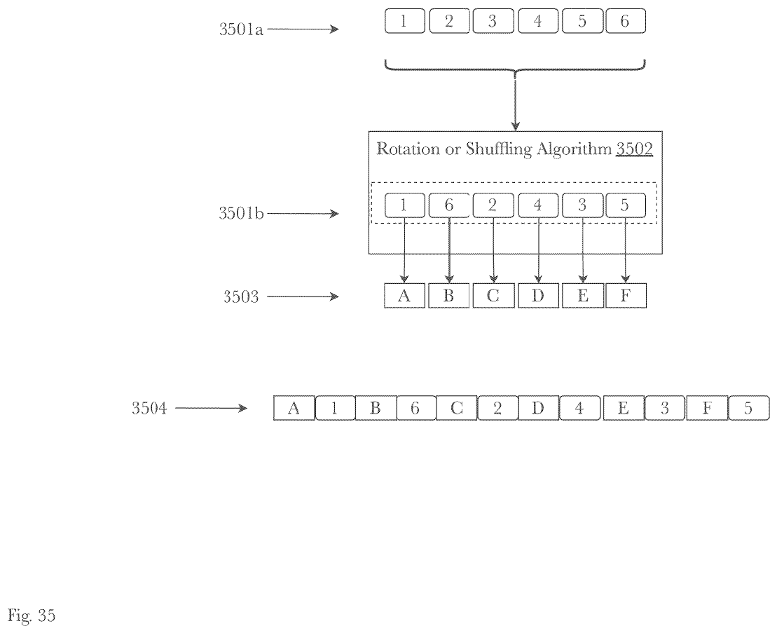

FIG. 35 is a diagram showing an exemplary codebook shuffling method. In this embodiment, rather than selecting codebooks for encoding based on their compaction efficiency, codebooks are selected either based on a rotating list or based on a shuffling algorithm. The methodology of this embodiment provides additional security to compacted data, as the data cannot be decoded without knowing the precise sequence of codebooks used to encode any given sourcepacket or data set.

Here, a list of six codebooks is selected for shuffling, each identified by a number from 1to 6 3501a. The list of codebooks is sent to a rotation or shuffling algorithm 3502, and reorganized according to the algorithm 3501b. The first six of a series of sourcepackets, each identified by a letter from A to E, 3503 is each encoded by one of the algorithms, in this case A is encoded by codebook 1, B is encoded by codebook 6, C is encoded by codebook 2, D is encoded by codebook 4, E is encoded by codebook 13 A is encoded by codebook 5. The encoded sourcepackets 3503 and their associated codebook identifiers 3501b are combined into a data structure 3504 in which each encoded sourcepacket is followed by the identifier of the codebook used to encode that particular sourcepacket.

According to an embodiment, the codebook rotation or shuffling algorithm 3502 may produce a random or pseudo-random selection of codebooks based on a function. Some non-limiting functions that may be used for shuffling include:
1. given a function f (n) which returns a codebook according to an input parameter n in the range 1 to N are, and given t the number of the current sourcepacket or sourceblock: f(t*M modulo p), where M is an arbitrary multiplying factor (1<=M<=p−1) which acts as a key, and p is a large prime number less than or equal to N;
2. f(A\hat{ }t modulo p), where A is a base relatively prime to p−1 which acts as a key, and p is a large prime number less than or equal to N;
3. f(floor(t*x) modulo N), and x is an irrational number chosen randomly to act as a key;
4. f(t XOR K) where the XOR is performed bit-wise on the binary representations of t and a key K with same number of bits in its representation of N. The function f(n) may return the nth codebook simply by referencing the nth element in a list of codebooks, or it could return the nth codebook given by a formula chosen by a user.

In one embodiment, prior to transmission, the endpoints (users or devices) of a transmission agree in advance about the rotation list or shuffling function to be used, along with any necessary input parameters such as a list order, function code, cryptographic key, or other indicator, depending on the requirements of the type of list or function being used. Once the rotation list or shuffling function is agreed, the endpoints can encode and decode transmissions from one another using the encodings set forth in the current codebook in the rotation or shuffle plus any necessary input parameters.

In some embodiments, the shuffling function may be restricted to permutations within a set of codewords of a given length.

Note that the rotation or shuffling algorithm is not limited to cycling through codebooks in a defined order. In some embodiments, the order may change in each round of encoding. In some embodiments, there may be no restrictions on repetition of the use of codebooks.

In some embodiments, codebooks may be chosen based on some combination of compaction performance and rotation or shuffling. For example, codebook shuffling may be repeatedly applied to each sourcepacket until a codebook is found that meets a minimum level of compaction for that sourcepacket. Thus, codebooks are chosen randomly or pseudo-randomly for each sourcepacket, but only those that produce encodings of the sourcepacket better than a threshold will be used.

### Description of Exemplary Aspects

Since the library consists of re-usable building sourceblocks, and the actual data is represented by reference codes to the library, the total storage space of a single set of data would be much smaller than conventional methods, wherein the data is stored in its entirety. The more data sets that are stored, the larger the library becomes, and the more data can be stored in reference code form.

As an analogy, imagine each data set as a collection of printed books that are only occasionally accessed. The amount of physical shelf space required to store many collections would be quite large, and is analogous to conventional methods of storing every single bit of data in every data set. Consider, however, storing all common elements within and across books in a single library, and storing the books as references codes to those common elements in that library. As a single book is added to the library, it will contain many repetitions of words and phrases. Instead of storing the whole words and phrases, they are added to a library, and given a reference code, and stored as reference codes. At this scale, some space savings may be achieved, but the reference codes will be on the order of the same size as the words themselves. As more books are added to the library, larger phrases, quotations, and other words patterns will become common among the books. The larger the word patterns, the smaller the reference codes will be in relation to them as not all possible word patterns will be used. As entire collections of books are added to the library, sentences, paragraphs, pages, or even whole books will become repetitive. There may be many duplicates of books within a collection and across multiple collections, many references and quotations from one book to another, and much common phraseology within books on particular subjects. If each unique page of a book is stored only once in a common library and given a reference code, then a book of 1,000 pages or more could be stored on a few printed pages as a string of codes referencing the proper full-sized pages in the common library. The physical space taken up by the books would be dramatically reduced. The more collections that are added, the greater the likelihood that phrases, paragraphs, pages, or entire books will already be in the library, and the more information in each collection of books can be stored in reference form. Accessing entire collections of books is then limited not by physical shelf space, but by the ability to reprint and recycle the books as needed for use.

The projected increase in storage capacity using the method herein described is primarily dependent on two factors: 1) the ratio of the number of bits in a block to the number of bits in the reference code, and 2) the amount of repetition in data being stored by the system.

With respect to the first factor, the number of bits used in the reference codes to the sourceblocks must be smaller than the number of bits in the sourceblocks themselves in order for any additional data storage capacity to be obtained. As a simple example, 16-bit sourceblocks would require 216, or 65536, unique reference codes to represent all possible patterns of bits. If all possible 65536 blocks patterns are utilized, then the reference code itself would also need to contain sixteen bits in order to refer to all possible 65,536 blocks patterns. In such case, there would be no storage savings. However, if only 16 of those block patterns are utilized, the reference code can be reduced to 4 bits in size, representing an effective compression of 4 times (16 bits/4 bits=4) versus conventional storage. Using a typical block size of 512 bytes, or 4,096 bits, the number of possible block patterns is 24,096, which for all practical purposes is unlimited. A typical hard drive contains one terabyte (TB) of physical storage capacity, which represents 1,953,125,000, or roughly 231, 512 byte blocks. Assuming that 1 TB of unique 512-byte sourceblocks were contained in the library, and that the reference code would thus need to be 31 bits long, the effective compression ratio for stored data would be on the order of 132 times (4,096/31≈ 132) that of conventional storage.

With respect to the second factor, in most cases it could be assumed that there would be sufficient repetition within a data set such that, when the data set is broken down into sourceblocks, its size within the library would be smaller than the original data. However, it is conceivable that the initial copy of a data set could require somewhat more storage space than the data stored in a conventional manner, if all or nearly all sourceblocks in that set were unique. For example, assuming that the reference codes are 1/10th the size of a full-sized copy, the first copy stored as sourceblocks in the library would need to be 1.1 megabytes (MB), (1 MB for the complete set of full-sized sourceblocks in the library and 0.1 MB for the reference codes). However, since the sourceblocks stored in the library are universal, the more duplicate copies of something you save, the greater efficiency versus conventional storage methods. Conventionally, storing 10 copies of the same data requires 10 times the storage space of a single copy. For example, ten copies of a 1 MB file would take up 10 MB of storage space. However, using the method described herein, only a single full-sized copy is stored, and subsequent copies are stored as reference codes. Each additional copy takes up only a fraction of the space of the full-sized copy. For example, again assuming that the reference codes are 1/10th the size of the full-size copy, ten copies of a 1 MB file would take up only 2 MB of space (1 MB for the full-sized copy, and 0.1 MB each for ten sets of reference codes). The larger the library, the more likely that part or all of incoming data will duplicate sourceblocks already existing in the library.

The size of the library could be reduced in a manner similar to storage of data. Where sourceblocks differ from each other only by a certain number of bits, instead of storing a new sourceblock that is very similar to one already existing in the library, the new sourceblock could be represented as a reference code to the existing sourceblock, plus information about which bits in the new block differ from the existing block. For example, in the case where 512 byte sourceblocks are being used, if the system receives a new sourceblock that differs by only one bit from a sourceblock already existing in the library, instead of storing a new 512 byte sourceblock, the new sourceblock could be stored as a reference code to the existing sourceblock, plus a reference to the bit that differs. Storing the new sourceblock as a reference code plus changes would require only a few bytes of physical storage space versus the 512 bytes that a full sourceblock would require. The algorithm could be optimized to store new sourceblocks in this reference code plus changes form unless the changes portion is large enough that it is more efficient to store a new, full sourceblock.

It will be understood by one skilled in the art that transfer and synchronization of data would be increased to the same extent as for storage. By transferring or synchronizing reference codes instead of full-sized data, the bandwidth requirements for both types of operations are dramatically reduced.

In addition, the method described herein is inherently a form of encryption. When the data is converted from its full form to reference codes, none of the original data is contained in the reference codes. Without access to the library of sourceblocks, it would be impossible to re-construct any portion of the data from the reference codes. This inherent property of the method described herein could obviate the need for traditional encryption algorithms, thereby offsetting most or all of the computational cost of conversion of data back and forth to reference codes. In theory, the method described herein should not utilize any additional computing power beyond traditional storage using encryption algorithms. Alternatively, the method described herein could be in addition to other encryption algorithms to increase data security even further.

In other embodiments, additional security features could be added, such as: creating a proprietary library of sourceblocks for proprietary networks, physical separation of the reference codes from the library of sourceblocks, storage of the library of sourceblocks on a removable device to enable easy physical separation of the library and reference codes from any network, and incorporation of proprietary sequences of how sourceblocks are read and the data reassembled.

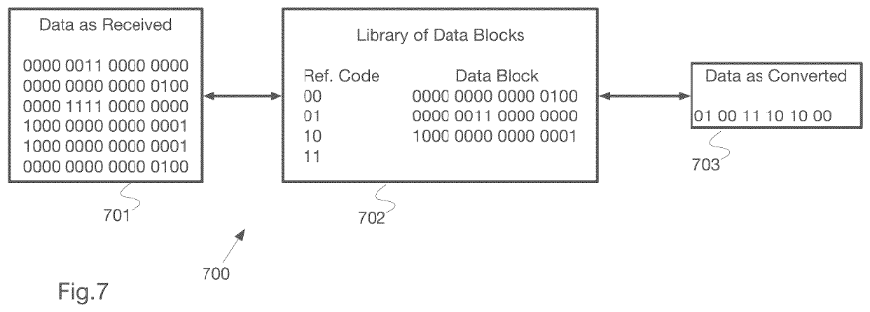

FIG. 7 is a diagram showing an example of how data might be converted into reference codes using an aspect of an embodiment 700. As data is received 701, it is read by the processor in sourceblocks of a size dynamically determined by the previously disclosed sourceblock size optimizer 410. In this example, each sourceblock is 16 bits in length, and the library 702 initially contains three sourceblocks with reference codes 00, 01, and 10. The entry for reference code 11is initially empty. As each 16 bit sourceblock is received, it is compared with the library. If that sourceblock is already contained in the library, it is assigned the corresponding reference code. So, for example, as the first line of data (0000 0011 0000 0000) is received, it is assigned the reference code (01) associated with that sourceblock in the library. If that sourceblock is not already contained in the library, as is the case with the third line of data (0000 1111 0000 0000) received in the example, that sourceblock is added to the library and assigned a reference code, in this case 11. The data is thus converted 703 to a series of reference codes to sourceblocks in the library. The data is stored as a collection of codewords, each of which contains the reference code to a sourceblock and information about the location of the sourceblocks in the data set. Reconstructing the data is performed by reversing the process. Each stored reference code in a data collection is compared with the reference codes in the library, the corresponding sourceblock is read from the library, and the data is reconstructed into its original form.

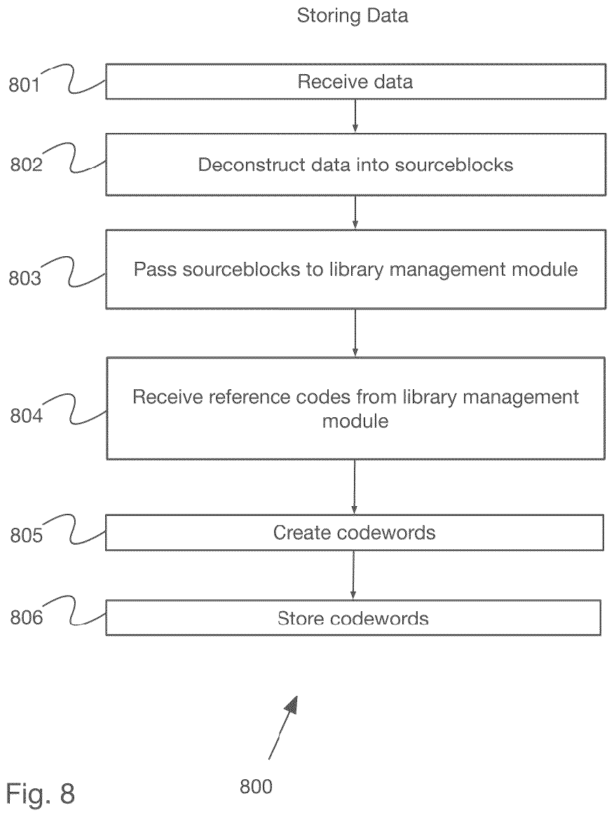

FIG. 8 is a method diagram showing the steps involved in using an embodiment 800 to store data. As data is received 801, it would be deconstructed into sourceblocks 802, and passed 803 to the library management module for processing. Reference codes are received back 804 from the library management module and may be combined with location information to create codewords 805, which are then be stored 806 as representations of the original data.

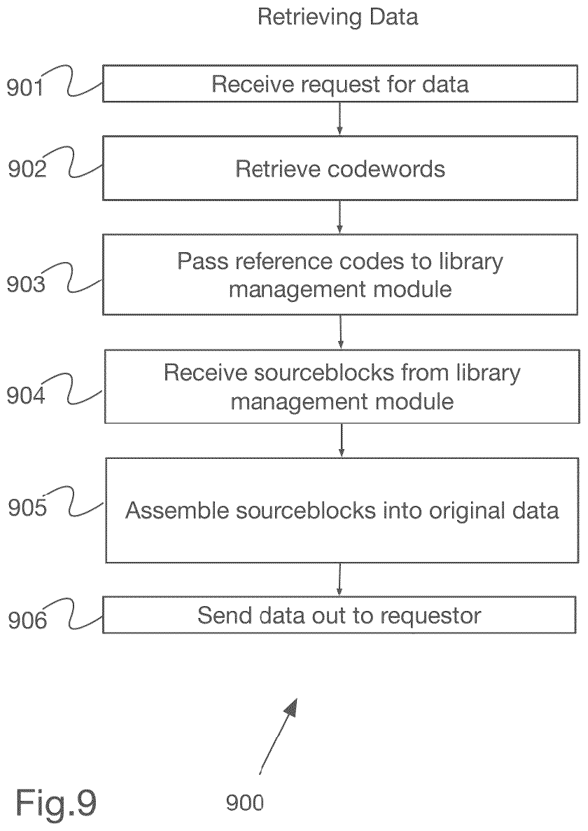

FIG. 9 is a method diagram showing the steps involved in using an embodiment 900 to retrieve data. When a request for data is received 901, the associated codewords would be retrieved 902 from the library. The codewords would be passed 903 to the library management module, and the associated sourceblocks would be received back 904. Upon receipt, the sourceblocks would be assembled 905 into the original data using the location data contained in the codewords, and the reconstructed data would be sent out 906 to the requestor.

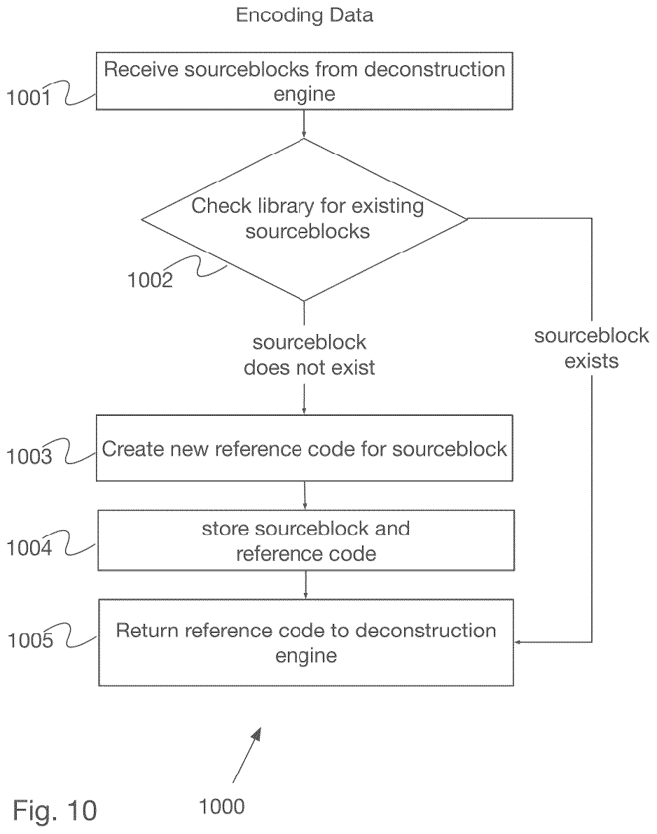

FIG. 10 is a method diagram showing the steps involved in using an embodiment 1000 to encode data. As sourceblocks are received 1001 from the deconstruction engine, they would be compared 1002 with the sourceblocks already contained in the library. If that sourceblock already exists in the library, the associated reference code would be returned 1005 to the deconstruction engine. If the sourceblock does not already exist in the library, a new reference code would be created 1003 for the sourceblock. The new reference code and its associated sourceblock would be stored 1004 in the library, and the reference code would be returned to the deconstruction engine.

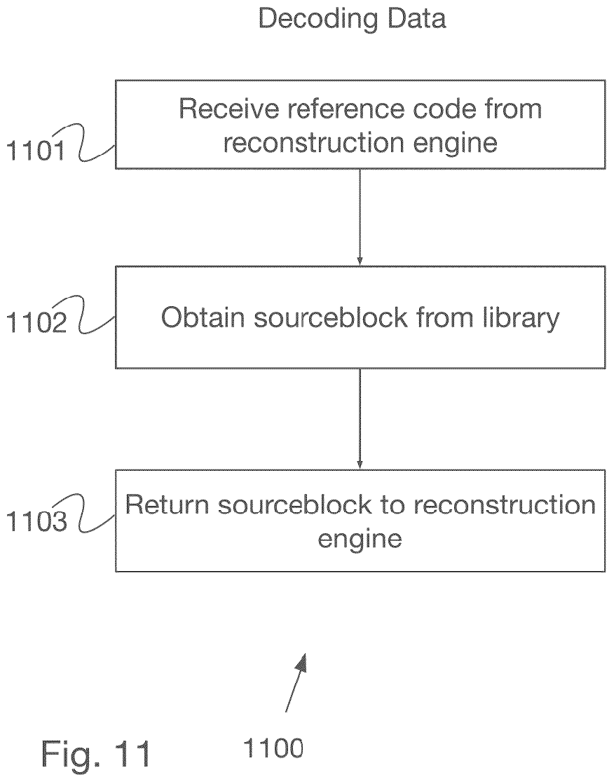

FIG. 11 is a method diagram showing the steps involved in using an embodiment 1100 to decode data. As reference codes are received 1101 from the reconstruction engine, the associated sourceblocks are retrieved 1102 from the library, and returned 1103 to the reconstruction engine.

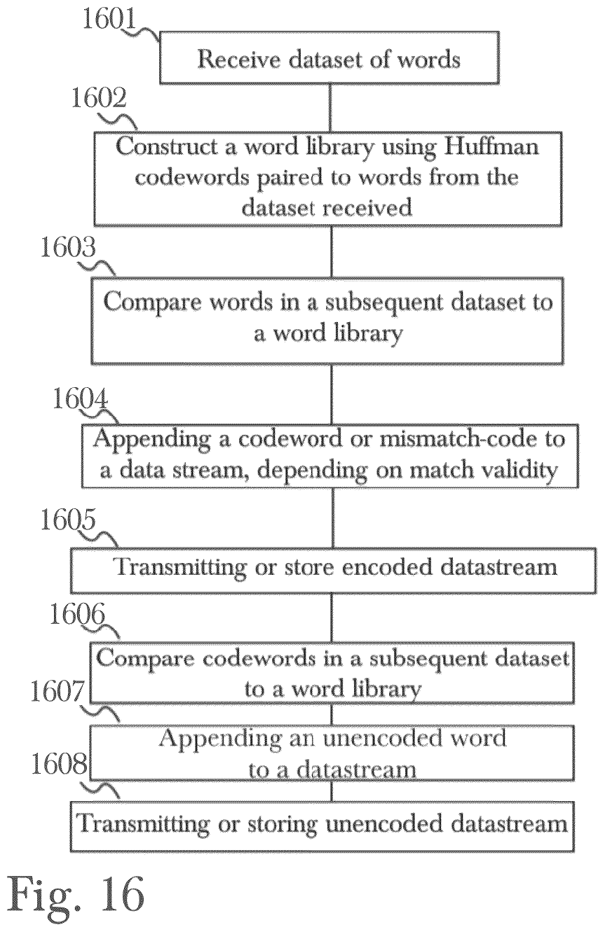

FIG. 16 is a method diagram illustrating key system functionality utilizing an encoder and decoder pair, according to a preferred embodiment. In a first step 1601, at least one incoming data set may be received at a customized library generator 1300 that then 1602 processes data to produce a customized word library 1201 comprising key-value pairs of data words (each comprising a string of bits) and their corresponding calculated binary Huffman codewords. A subsequent dataset may be received and compared to word library 1603 to determine proper codewords to use in order to encode the dataset. Words in the dataset are checked against the word library and appropriate encodings are appended to a data stream 1604. If a word is mismatched within the word library and the dataset, meaning that it is present in the dataset but not the word library, then a mismatched code is appended, followed by the unencoded original word. If a word has a match within the word library, then the appropriate codeword in the word library is appended to the data stream. Such a data stream may then be stored or transmitted 1605 to a destination as desired. For the purposes of decoding, an already-encoded data stream may be received and compared 1606, and un-encoded words may be appended to a new data stream 1607 depending on word matches found between the encoded data stream and the word library that is present. A matching codeword that is found in a word library is replaced with the matching word and appended to a data stream, and a mismatch code found in a data stream is deleted and the following unencoded word is re-appended to a new data stream, the inverse of the process of encoding described earlier. Such a data stream may then be stored or transmitted 1608 as desired.

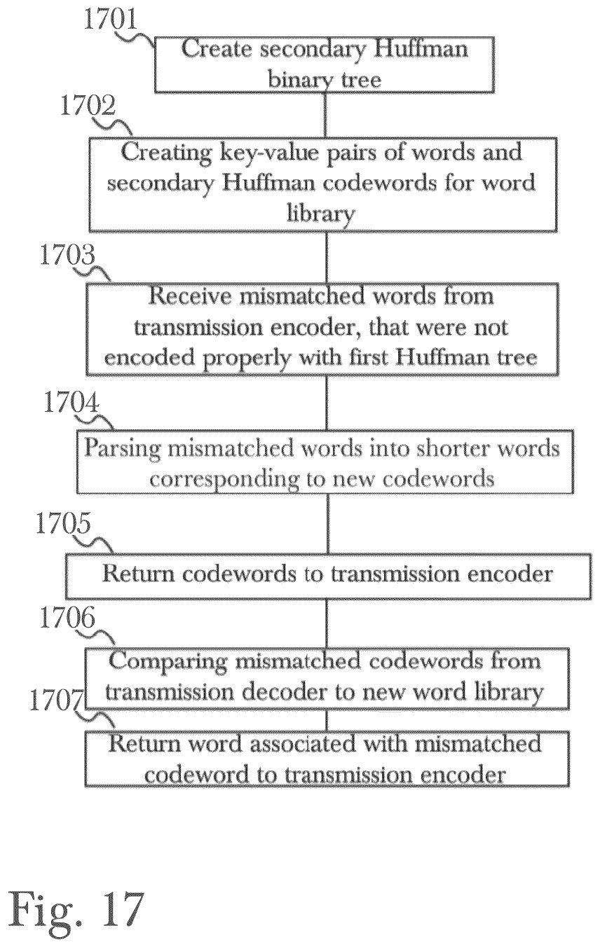

FIG. 17 is a method diagram illustrating possible use of a hybrid encoder/decoder to improve the compression ratio, according to a preferred aspect. A second Huffman binary tree may be created 1701, having a shorter maximum length of codewords than a first Huffman binary tree 1602, allowing a word library to be filled with every combination of codeword possible in this shorter Huffman binary tree 1702. A word library may be filled with these Huffman codewords and words from a dataset 1702, such that a hybrid encoder/decoder 1304, 1503 may receive any mismatched words from a dataset for which encoding has been attempted with a first Huffman binary tree 1703, 1604 and parse previously mismatched words into new partial codewords (that is, codewords that are each a substring of an original mismatched codeword) using the second Huffman binary tree 1704. In this way, an incomplete word library may be supplemented by a second word library. New codewords attained in this way may then be returned to a transmission encoder 1705, 1500. In the event that an encoded dataset is received for decoding, and there is a mismatch code indicating that additional coding is needed, a mismatch code may be removed and the unencoded word used to generate a new codeword as before 1706, so that a transmission encoder 1500 may have the word and newly generated codeword added to its word library 1707, to prevent further mismatching and errors in encoding and decoding.

It will be recognized by a person skilled in the art that the methods described herein can be applied to data in any form. For example, the method described herein could be used to store genetic data, which has four data units: C, G, A, and T. Those four data units can be represented as 2 bit sequences: 00, 01, 10, and 11, which can be processed and stored using the method described herein.

It will be recognized by a person skilled in the art that certain embodiments of the methods described herein may have uses other than data storage. For example, because the data is stored in reference code form, it cannot be reconstructed without the availability of the library of sourceblocks. This is effectively a form of encryption, which could be used for cyber security purposes. As another example, an embodiment of the method described herein could be used to store backup copies of data, provide for redundancy in the event of server failure, or provide additional security against cyberattacks by distributing multiple partial copies of the library among computers are various locations, ensuring that at least two copies of each sourceblock exist in different locations within the network.

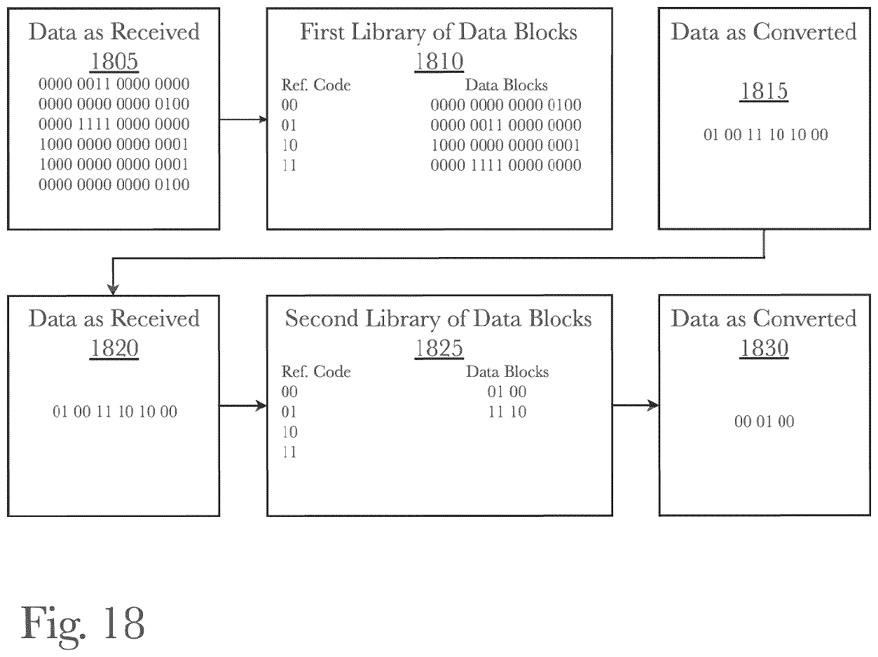

FIG. 18 is a flow diagram illustrating the use of a data encoding system used to recursively encode data to further reduce data size. Data may be input 1805 into a data deconstruction engine 102 to be deconstructed into code references, using a library of code references based on the input 1810. Such example data is shown in a converted, encoded format 1815, highly compressed, reducing the example data from 96 bits of data, to 12 bits of data, before sending this newly encoded data through the process again 1820, to be encoded by a second library 1825, reducing it even further. The newly converted data 1830 is shown as only 6 bits in this example, thus a size of 6.25% of the original data packet. With recursive encoding, then, it is possible and implemented in the system to achieve increasing compression ratios, using multi-layered encoding, through recursively encoding data. Both initial encoding libraries 1810 and subsequent libraries 1825 may be achieved through machine learning techniques to find optimal encoding patterns to reduce size, with the libraries being distributed to recipients prior to transfer of the actual encoded data, such that only the compressed data 1830 must be transferred or stored, allowing for smaller data footprints and bandwidth requirements. This process can be reversed to reconstruct the data. While this example shows only two levels of encoding, recursive encoding may be repeated any number of times. The number of levels of recursive encoding will depend on many factors, a non-exhaustive list of which includes the type of data being encoded, the size of the original data, the intended usage of the data, the number of instances of data being stored, and available storage space for codebooks and libraries. Additionally, recursive encoding can be applied not only to data to be stored or transmitted, but also to the codebooks and/or libraries, themselves. For example, many installations of different libraries could take up a substantial amount of storage space. Recursively encoding those different libraries to a single, universal library would dramatically reduce the amount of storage space required, and each different library could be reconstructed as necessary to reconstruct incoming streams of data.

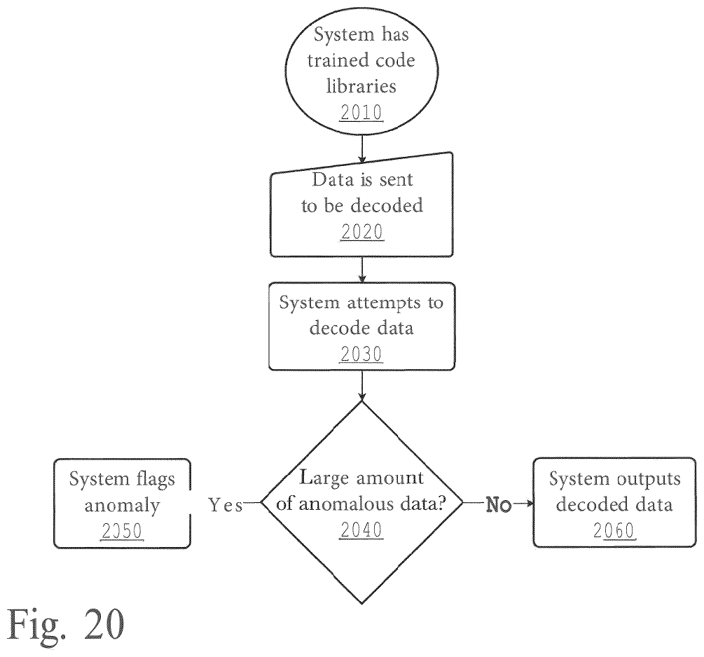

FIG. 20 is a flow diagram of an exemplary method used to detect anomalies in received encoded data and producing a warning. A system may have trained encoding libraries 2010, before data is received from some source such as a network connected device or a locally connected device including USB connected devices, to be decoded 2020. Decoding in this context refers to the process of using the encoding libraries to take the received data and attempt to use encoded references to decode the data into its original source 2030, potentially more than once if recursive encoding was used, but not necessarily more than once. An anomaly detector 1910 may be configured to detect a large amount of un-encoded data 2040 in the midst of encoded data, by locating data or references that do not appear in the encoding libraries, indicating at least an anomaly, and potentially data tampering or faulty encoding libraries. A flag or warning is set by the system 2050, allowing a user to be warned at least of the presence of the anomaly and the characteristics of the anomaly. However, if a large amount of invalid references or unencoded data are not present in the encoded data that is attempting to be decoded, the data may be decoded and output as normal 2060, indicating no anomaly has been detected.

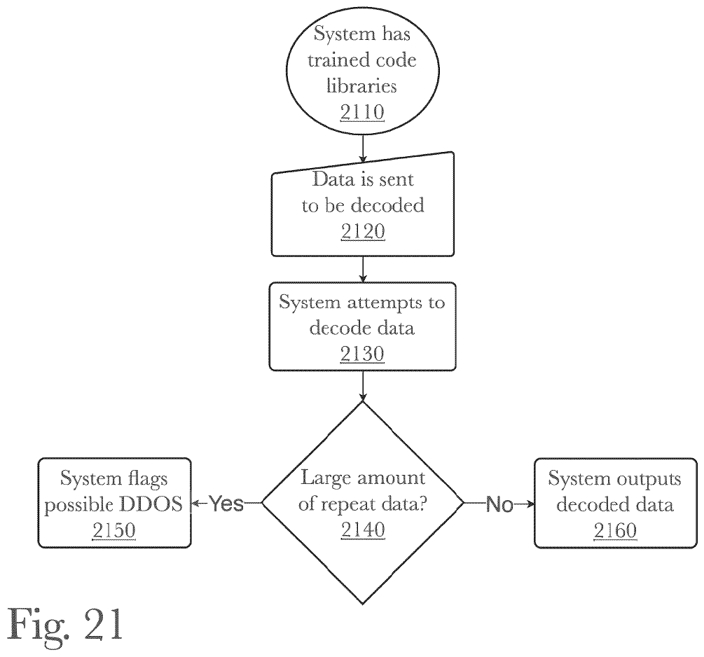

FIG. 21 is a flow diagram of a method used for Distributed Denial of Service (DDoS) attack denial. A system may have trained encoding libraries 2110, before data is received from some source such as a network connected device or a locally connected device including USB connected devices, to be decoded 2120. Decoding in this context refers to the process of using the encoding libraries to take the received data and attempt to use encoded references to decode the data into its original source 2130, potentially more than once if recursive encoding was used, but not necessarily more than once. A DDOS detector 1920 may be configured to detect a large amount of repeating data 2140 in the encoded data, by locating data or references that repeat many times over (the number of which can be configured by a user or administrator as need be), indicating a possible DDOS attack. A flag or warning is set by the system 2150, allowing a user to be warned at least of the presence of a possible DDOS attack, including characteristics about the data and source that initiated the flag, allowing a user to then block incoming data from that source. However, if a large amount of repeat data in a short span of time is not detected, the data may be decoded and output as normal 2160, indicating no DDOS attack has been detected.

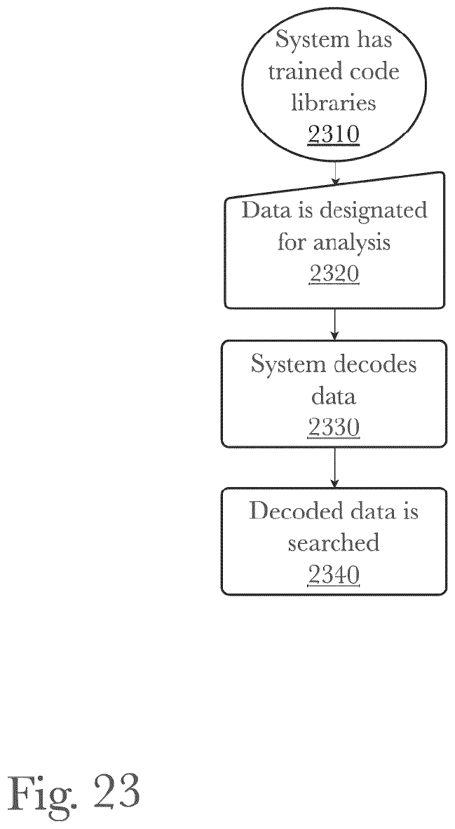

FIG. 23 is a flow diagram of an exemplary method used to enable high-speed data mining of repetitive data. A system may have trained encoding libraries 2310, before data is received from some source such as a network connected device or a locally connected device including USB connected devices, to be analyzed 2320 and decoded 2330. When determining data for analysis, users may select specific data to designate for decoding 2330, before running any data mining or analytics functions or software on the decoded data 2340. Rather than having traditional decryption and decompression operate over distributed drives, data can be regenerated immediately using the encoding libraries disclosed herein, as it is being searched. Using methods described in FIG. 9 and FIG. 11, data can be stored, retrieved, and decoded swiftly for searching, even across multiple devices, because the encoding library may be on each device. For example, if a group of servers host codewords relevant for data mining purposes, a single computer can request these codewords, and the codewords can be sent to the recipient swiftly over the bandwidth of their connection, allowing the recipient to locally decode the data for immediate evaluation and searching, rather than running slow, traditional decompression algorithms on data stored across multiple devices or transfer larger sums of data across limited bandwidth.

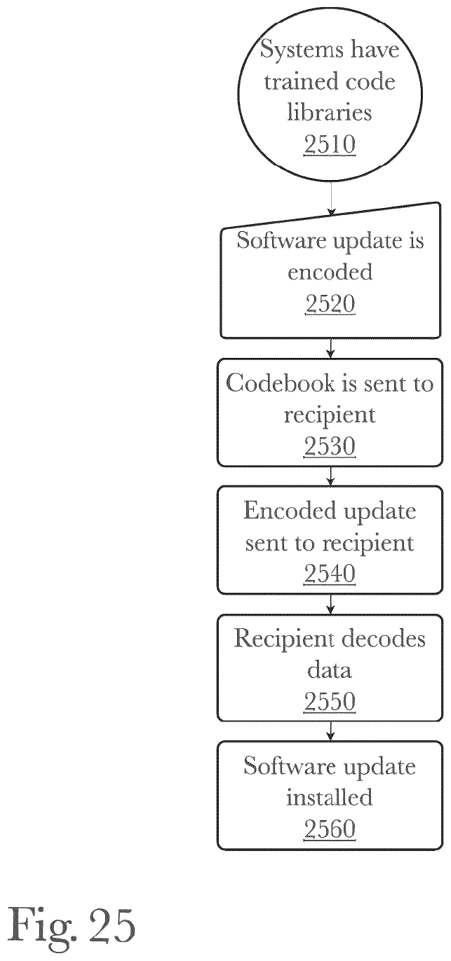

FIG. 25 is a flow diagram of an exemplary method used to encode and transfer software and firmware updates to a device for installation, for the purposes of reduced bandwidth consumption. A first system may have trained code libraries or “codebooks” present 2510, allowing for a software update of some manner to be encoded 2520. Such a software update may be a firmware update, operating system update, security patch, application patch or upgrade, or any other type of software update, patch, modification, or upgrade, affecting any computer system. A codebook for the patch must be distributed to a recipient 2530, which may be done beforehand and either over a network or through a local or physical connection, but must be accomplished at some point in the process before the update may be installed on the recipient device 2560. An update may then be distributed to a recipient device 2540, allowing a recipient with a codebook distributed to them 2530 to decode the update 2550 before installation 2560. In this way, an encoded and thus heavily compressed update may be sent to a recipient far quicker and with less bandwidth usage than traditional lossless compression methods for data, or when sending data in uncompressed formats. This especially may benefit large distributions of software and software updates, as with enterprises updating large numbers of devices at once.

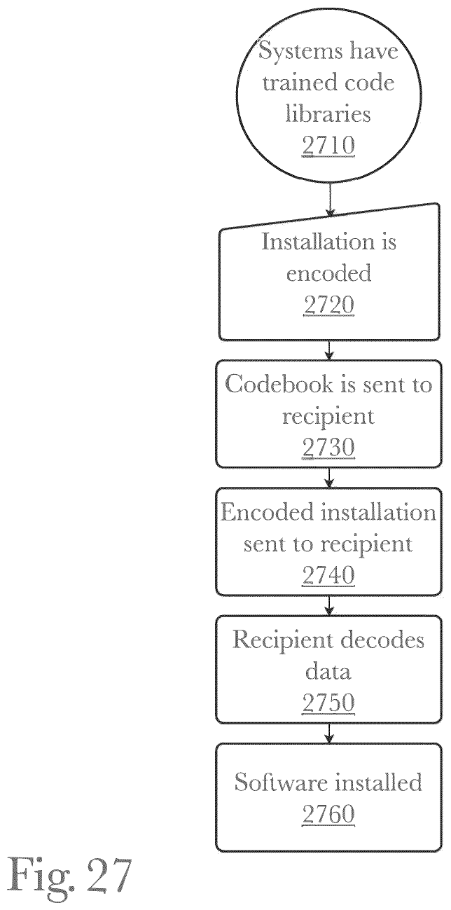

FIG. 27 is a flow diagram of an exemplary method used to encode new software and operating system installations for reduced bandwidth required for transference. A first system may have trained code libraries or “codebooks” present 2710, allowing for a software installation of some manner to be encoded 2720. Such a software installation may be a software update, operating system, security system, application, or any other type of software installation, execution, or acquisition, affecting a computer system. An encoding library or “codebook” for the installation must be distributed to a recipient 2730, which may be done beforehand and either over a network or through a local or physical connection, but must be accomplished at some point in the process before the installation can begin on the recipient device 2760. An installation may then be distributed to a recipient device 2740, allowing a recipient with a codebook distributed to them 2730 to decode the installation 2750 before executing the installation 2760. In this way, an encoded and thus heavily compressed software installation may be sent to a recipient far quicker and with less bandwidth usage than traditional lossless compression methods for data, or when sending data in uncompressed formats. This especially may benefit large distributions of software and software updates, as with enterprises updating large numbers of devices at once.

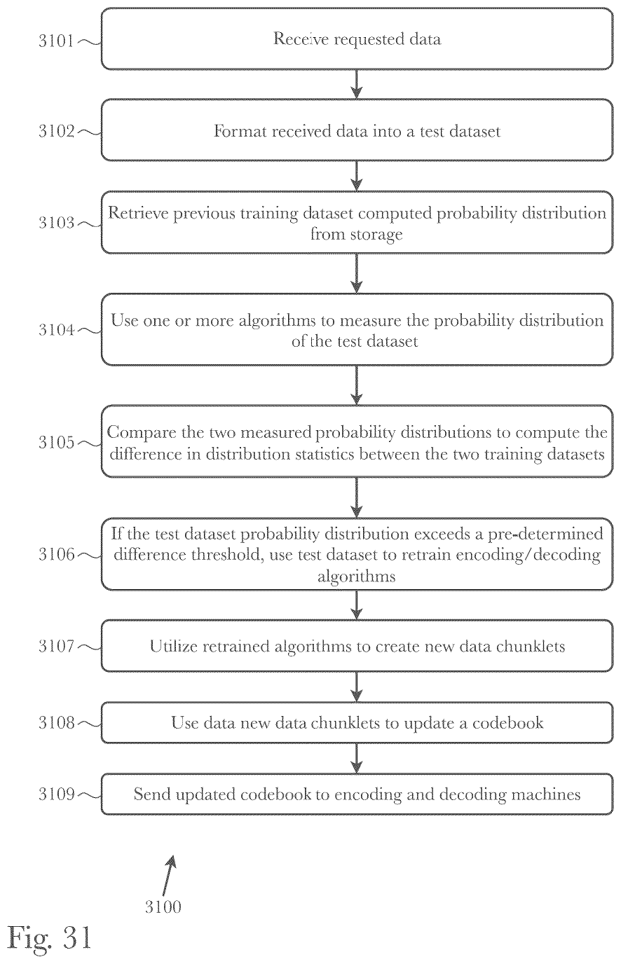

FIG. 31 is a method diagram illustrating the steps 3100 involved in using an embodiment of the codebook training system to update a codebook. The process begins when requested data is received 3101 by a codebook training module. The requested data may comprise a plurality of sourceblocks. Next, the received data may be stored in a cache and formatted into a test dataset 3102. The next step is to retrieve the previously computed probability distribution associated with the previous (most recent) training dataset from a storage device 3103. Using one or more algorithms, measure and record the probability distribution of the test dataset 3104. The step after that is to compare the measured probability distributions of the test dataset and the previous training dataset to compute the difference in distribution statistics between the two datasets 3105. If the test dataset probability distribution exceeds a pre-determined difference threshold, then the test dataset will be used to retrain the encoding/decoding algorithms 3106 to reflect the new distribution of the incoming data to the encoder/decoder system. The retrained algorithms may then be used to create new data sourceblocks 3107 that better capture the nature of the data being received. These newly created data sourceblocks may then be used to create new codewords and update a codebook 3108 with each new data sourceblock and its associated new codeword. Last, the updated codebooks may be sent to encoding and decoding machines 3109 in order to ensure the encoding/decoding system function properly.

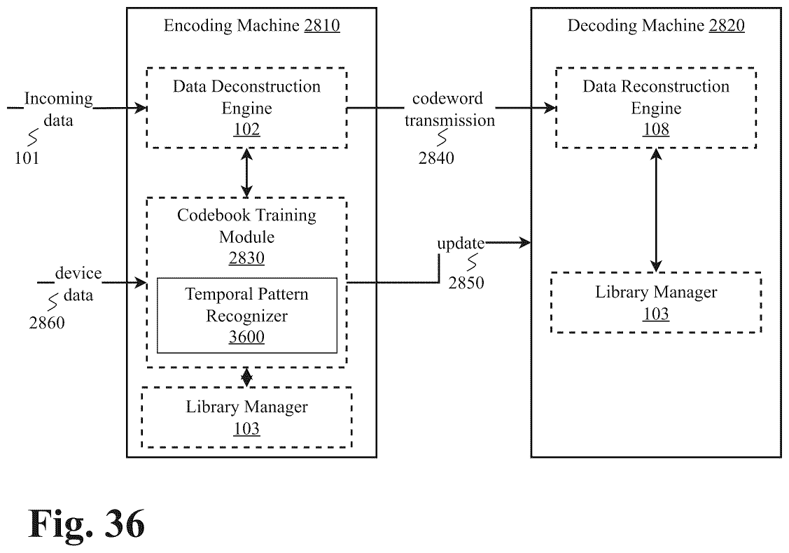

FIG. 36 is a diagram showing an exemplary system architecture incorporating temporal pattern recognition capabilities for codebook-based data encoding. As incoming data 101 enters the system, it is received by data deconstruction engine 102 residing on encoding machine 2810. Data deconstruction engine 102 serves to break down the incoming data into sourcepackets and further into sourceblocks of appropriate sizes for encoding. After initial processing, these sourceblocks flow to codebook training module 2830 for further analysis and codebook optimization.

Codebook training module 2830 contains an integrated temporal pattern recognizer 3600, which represents an enhancement to the system's encoding capabilities. Temporal pattern recognizer 3600 designed to identify, analyze, and leverage time-based patterns within data to improve encoding efficiency. Unlike traditional encoding approaches that treat each data segment in isolation, temporal pattern recognizer 3600 examines relationships between data across time dimensions, enabling the system to exploit temporal redundancies and patterns that would otherwise remain undetected.

Temporal pattern recognizer 3600 receives input from two primary sources: processed data flowing from data deconstruction engine 102 and device data 2860. The processed data provides the actual content to be analyzed for temporal patterns, while device data 2860 supplies contextual information that may include timestamps, sequence identifiers, sampling rates, or other chronological metadata that helps establish temporal relationships within the data. For example, in a system processing sensor data, device data 2860 might include sampling timestamps that allow temporal pattern recognizer 3600 to correlate readings with specific times of day, days of week, or seasonal periods.

Within temporal pattern recognizer 3600, time-series analysis algorithms examine the data to detect recurring patterns across various time scales. These patterns might include diurnal cycles (day/night variations), weekly patterns (workday versus weekend behavior), monthly cycles, seasonal trends, or any other time-correlated data characteristics. By identifying these patterns, temporal pattern recognizer 3600 can predict which types of data are likely to occur in specific temporal contexts, allowing for more efficient encoding strategies tailored to those contexts.

For example, if the system processes network traffic data, temporal pattern recognizer 3600 might discover that certain types of packets predominate during business hours while others are more common during overnight periods. This knowledge enables the system to prepare and select different codebooks optimized for each temporal context, rather than using a single general-purpose codebook that offers only average efficiency across all contexts.

After analyzing the temporal patterns, temporal pattern recognizer 3600 communicates with library manager 103 on encoding machine 2810. Library manager 103 maintains the collection of codebooks and, based on input from temporal pattern recognizer 3600, creates, selects, and manages temporally-optimized codebooks for different identified temporal contexts. These temporally-optimized codebooks provide significantly better compression ratios compared to generic codebooks, as they are specifically tailored to the data patterns that occur within particular time contexts.

When data has been encoded using the temporally-optimized codebooks, it is transmitted as codewords 2840 to data reconstruction engine 108 on decoding machine 2820. The codewords 2840 include not only the encoded data but also references to which temporally-optimized codebooks were used for encoding, ensuring that the reconstruction process can correctly reverse the encoding.

To maintain synchronization between encoding and decoding processes, codebook training module 2830 periodically sends codebook updates 2850 to decoding machine 2820. These updates contain newly generated or refined temporally-optimized codebooks along with metadata that describes their temporal applicability (e.g., “business hours codebook,” “weekend codebook,” “end-of-month financial reporting codebook”). This ensures that library manager 103 on decoding machine 2820 has access to the same temporally-optimized codebooks used during encoding.

Data reconstruction engine 108 works with library manager 103 on decoding machine 2820 to select the appropriate temporally-optimized codebooks based on the metadata received with the codewords. By using the same temporally-optimized codebooks that were used during encoding, data reconstruction engine 108 can accurately reconstruct the original data.

The integration of temporal pattern recognizer 3600 into the codebook-based encoding system represents a significant advancement over conventional approaches that do not consider temporal context. By recognizing and exploiting temporal patterns, the system achieves superior compression ratios, reduced transmission bandwidth requirements, and enhanced security through the use of multiple codebooks that vary with temporal context. This temporal awareness is particularly valuable for data streams that exhibit strong time-based patterns, such as user activity logs, network traffic, sensor readings, financial transactions, and other time-series data commonly encountered in modern computing environments.

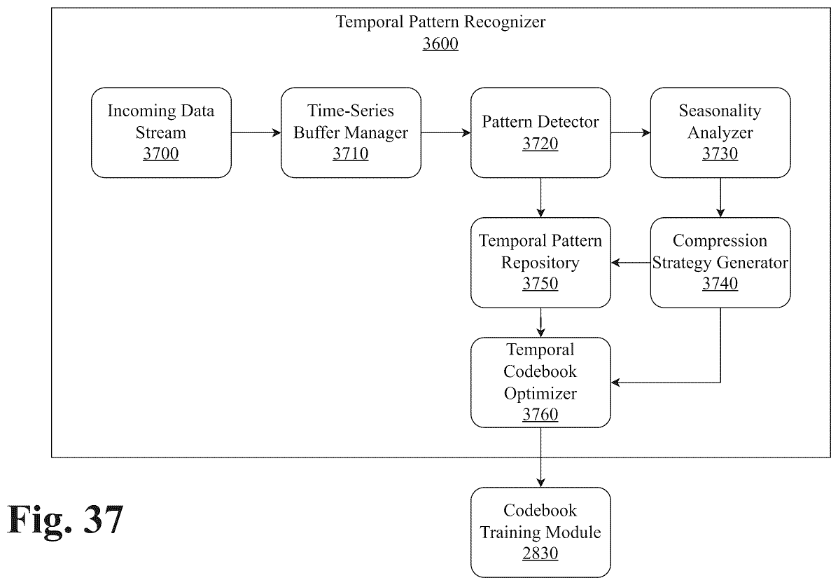

FIG. 37 is a diagram showing an exemplary architecture of temporal pattern recognizer, illustrating its internal components and data flow. This data stream may comprise various types of time-series data, such as but not limited to network traffic, sensor readings, user activity logs, financial transactions, or any other data that exhibits patterns over time. The temporal nature of this data may be explicit through included timestamps or implicit through the sequential ordering of data elements. For example, in a system processing IoT sensor data, incoming data stream 3700 would contain readings from multiple sensors along with temporal metadata indicating when each reading was captured.

A time-series buffer manager 3710 receives the incoming data and organizes it into chronologically ordered buffers that facilitate temporal analysis. Buffer manager 3710 implements sophisticated windowing strategies to capture data at multiple time scales simultaneously. These windows might include short-term buffers (seconds to minutes), medium-term buffers (hours to days), and long-term buffers (weeks to months), enabling the detection of patterns across various temporal granularities. In a healthcare monitoring application, for instance, buffer manager 3710 might maintain 24-hour windows for detecting daily patterns in vital signs, weekly windows for identifying trends across days, and monthly windows for observing longer-term health patterns. Buffer manager 3710 also handles the synchronization of data from multiple sources when timestamps may not perfectly align, ensuring that temporal relationships are preserved for accurate pattern detection.

A pattern detector 3720 analyzes the buffered data to identify recurring patterns, trends, and anomalies across different time scales. Detector 3720 employs a suite of statistical and machine learning algorithms specifically designed for time-series analysis, including but not limited to autocorrelation functions, Fourier transforms, and wavelet analysis to decompose complex time-series into constituent patterns. For example, when processing web server logs, pattern detector 3720 might identify characteristic traffic signatures associated with daily business hours, weekly promotional periods, or monthly billing cycles. These patterns are quantified according to their frequency, consistency, and significance, with higher confidence assigned to patterns that appear regularly and with minimal variation. Pattern detector 3720 can also identify trend changes that might indicate shifts in data characteristics requiring adaptation of encoding strategies.

A seasonality analyzer 3730 works in conjunction with pattern detector 3720 but specializes in identifying and characterizing cyclical patterns at specific temporal intervals. Analyzer 3730 focuses on detecting daily, weekly, monthly, quarterly, and annual cycles that are common in many types of data. For example, in retail sales data, seasonality analyzer 3730 might detect not only increased transaction volumes during weekends but also holiday shopping patterns, end-of-month paycheck-driven spending, and annual seasonal variations. These seasonality insights are particularly valuable for encoding optimization because they allow the system to anticipate and prepare for predictable shifts in data characteristics. Seasonality analyzer 3730 maintains statistical models of each identified seasonal pattern, including measures of regularity, amplitude, and phase, which inform the creation of season-specific encoding strategies.

A compression strategy generator 3740 translates the identified temporal patterns and seasonality insights into concrete encoding optimization strategies. Generator 3740 determines which characteristics of the data are most important to optimize for in each temporal context and develops tailored approaches to maximize encoding efficiency within those contexts. For instance, in a system processing video surveillance data, compression strategy generator 3740 might develop strategies optimized for daytime footage (characterized by high movement and color variation) versus nighttime footage (characterized by low light and minimal movement). Generator 3740 considers multiple optimization dimensions, including compression ratio, processing speed, and error resilience, potentially creating different strategies for different operational priorities. The generated strategies are formalized as sets of encoding parameters, codebook selection criteria, and sourceblock sizing recommendations that collectively maximize encoding performance for specific temporal contexts.

A temporal pattern repository 3750 serves as the knowledge base for storing discovered patterns, seasonality models, and their associated compression strategies. Repository 3750 maintains a comprehensive catalog of temporal patterns identified in the data, along with metadata describing their statistical properties, historical reliability, and applicability conditions. This historical record allows the system to track how patterns evolve over time and to make increasingly refined predictions about future data characteristics. For example, repository 3750 might track how network traffic patterns change as an organization grows, enabling the encoding system to adapt proactively rather than reactively. Repository 3750 also facilitates pattern comparison across different data sources and time periods, enabling the identification of correlations that might not be apparent within individual data streams.

A temporal codebook optimizer 3760 serves as the final integration point between the temporal pattern recognition components and codebook training module 2830. Optimizer 3760 translates the compression strategies generated by compression strategy generator 3740 into specific codebook optimization directives. These directives guide the creation, selection, and management of codebooks that are specially tuned for different temporal contexts. For example, optimizer 3760 might direct the creation of workday-specific and weekend-specific codebooks for encoding enterprise network traffic, each optimized for the characteristic data patterns observed during those periods. Optimizer 3760 also determines the appropriate criteria for switching between different temporally-optimized codebooks based on detected temporal context changes. These switching criteria are carefully designed to balance encoding efficiency against the overhead of frequent codebook changes. Optimizer 3760 provides feedback to the other components of temporal pattern recognizer 3600 regarding the actual performance improvements achieved through temporal optimization, enabling continuous refinement of the pattern detection and strategy generation processes.

The output from temporal codebook optimizer 3760 flows to codebook training module 2830, which incorporates the temporal optimization directives into its codebook generation and management processes. This integration enables the broader encoding system to leverage the temporal insights gained through the specialized analysis performed within temporal pattern recognizer 3600, resulting in significantly improved encoding efficiency compared to systems that do not consider temporal context.

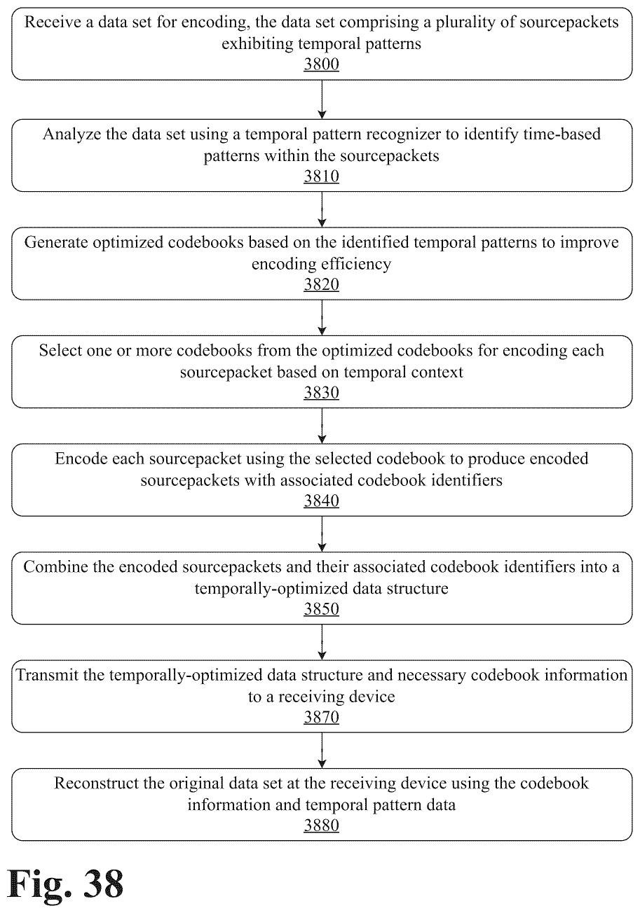

FIG. 38 is a flow diagram illustrating an exemplary method for temporal pattern recognition for encoding data. In a first step 3800, receive a data set for encoding, the data set comprising a plurality of sourcepackets exhibiting temporal patterns. This initial step involves the acquisition of data from one or more sources, which may include network traffic, sensor readings, user activity logs, financial transactions, media streams, or any other form of digital information that contains patterns that change over time. The data may arrive through various input channels, such as network interfaces, file system access, direct memory transfers, or streaming protocols. As the data arrives, it is temporarily stored in memory buffers or queues to prepare for processing. The incoming data is not simply a random collection of bits but rather contains inherent temporal relationships that can be exploited for more efficient encoding. For example, if processing enterprise network traffic, the received data might include packet headers, payload contents, and timestamp information that collectively reveal usage patterns throughout a business day.

In a step 3810, analyze the data set using a temporal pattern recognizer to identify time-based patterns within the sourcepackets. During this analysis phase, sophisticated algorithms examine the data across multiple time scales to detect recurring patterns, trends, cycles, and anomalies. The analysis begins by organizing the data chronologically and establishing temporal windows that capture short-term, medium-term, and long-term patterns. Statistical methods such as autocorrelation, Fourier analysis, and wavelet decomposition are applied to identify periodic structures within the data. Machine learning techniques may also be employed to classify temporal patterns and predict future data characteristics based on historical observations. For instance, when analyzing web server logs, the analysis might reveal distinct traffic profiles for morning hours, lunch breaks, afternoon work periods, and after-hours maintenance, each with characteristic data compositions that can be leveraged for encoding optimization.

In a step 3820, generate optimized codebooks based on the identified temporal patterns to improve encoding efficiency. This codebook generation process takes the temporal insights gained from the previous analysis and translates them into concrete encoding strategies. For each significant temporal pattern identified, a specialized codebook is created that is specifically optimized for the data characteristics associated with that pattern. These codebooks are designed to provide maximum compression efficiency for their respective temporal contexts. The generation process involves statistical analysis of the frequency distributions of data patterns within each temporal context, followed by the application of entropy-based algorithms like Huffman coding to create optimal codebook entries. For example, if processing IoT sensor data, separate codebooks might be generated for daytime active periods (when sensors report frequently changing values) and nighttime quiescent periods (when sensor values remain relatively stable), with each codebook optimized for the respective data characteristics.

In a step 3830, select one or more codebooks from the optimized codebooks for encoding each sourcepacket based on temporal context. This selection process evaluates each incoming sourcepacket to determine its temporal context and then chooses the most appropriate codebook from the available set of temporally-optimized codebooks. The selection criteria include matching the sourcepacket's timestamp or sequence position against known temporal patterns, analyzing the sourcepacket's content characteristics, and considering the current operational state. In cases where a sourcepacket spans multiple temporal contexts, either select a compromise codebook that performs reasonably well across the contexts or segment the sourcepacket along temporal boundaries to encode each segment with its optimal codebook. For instance, when processing video surveillance footage, automatically switch between day-optimized and night-optimized codebooks as lighting conditions change, ensuring optimal encoding efficiency throughout the 24-hour cycle.

In a step 3840, encode each sourcepacket using the selected codebook to produce encoded sourcepackets with associated codebook identifiers. The actual encoding operation involves transforming the original data into a more compact representation using the reference codes from the selected codebook. Each sourcepacket is processed according to the encoding algorithm defined for the process, but with the key enhancement that the codebook used for lookup is specifically optimized for the sourcepacket's temporal context. As each sourcepacket is encoded, attach a codebook identifier to the resulting encoded data, indicating which of the temporally-optimized codebooks was used for that particular sourcepacket. This identifier is essential for the subsequent decoding process to ensure that the correct codebook is used for reconstruction. For example, in processing financial transaction data, a sourcepacket containing end-of-month reconciliation data would be encoded using a codebook optimized for that specific temporal context, with the encoded output tagged with an identifier for the “end-of-month” codebook.

In a step 3850, combine the encoded sourcepackets and their associated codebook identifiers into a temporally-optimized data structure. This combination step creates a cohesive and organized representation of the encoded data that preserves all necessary information for later reconstruction. The data structure typically includes header information describing the overall encoding parameters, followed by a sequence of encoded sourcepackets, each with its associated metadata including the codebook identifier. The structure may also include synchronization markers, error detection codes, and other auxiliary information to ensure data integrity. The organization of this data structure is designed to facilitate efficient storage and transmission while maintaining the temporal relationships between encoded sourcepackets. For instance, the data structure might include a chronological index that allows for rapid access to data from specific time periods without requiring a full sequential scan of the encoded data.

In a step 3870, transmit the temporally-optimized data structure and necessary codebook information to a receiving device. This transmission step involves sending both the encoded data and the codebooks required for decoding over a communication channel to the intended recipient. Depending on the operational model, the codebooks may be transmitted alongside the encoded data, sent as separate updates when new temporal patterns are identified, or pre-distributed and referenced by identifier during transmission. The transmission protocol ensures that the receiving device has all necessary information to reconstruct the original data, including any temporal context information required for proper codebook selection. For example, in distributing software updates to IoT devices, the encoded update packages would be transmitted along with any new codebooks optimized for the current generation of device firmware, ensuring efficient transfer even as the underlying software architecture evolves over time.

In a step 3880, reconstruct the original data set at the receiving device using the codebook information and temporal pattern data. This reconstruction process reverses the encoding operations performed earlier, transforming the compact encoded representation back into the original data. For each encoded sourcepacket in the received data structure, identify the associated codebook identifier, retrieve the corresponding codebook, and use it to look up the original data patterns. These reconstructed patterns are then assembled in the proper sequence to regenerate the complete original data set. The temporal context information embedded in the encoding process ensures that the correct codebook is used for each portion of the data, maintaining encoding efficiency without sacrificing reconstruction accuracy. For instance, when reconstructing a day's worth of network monitoring data, the receiving device would automatically use morning-optimized codebooks for morning data segments, afternoon-optimized codebooks for afternoon segments, and so on, ensuring high-fidelity reconstruction throughout the temporal sequence.

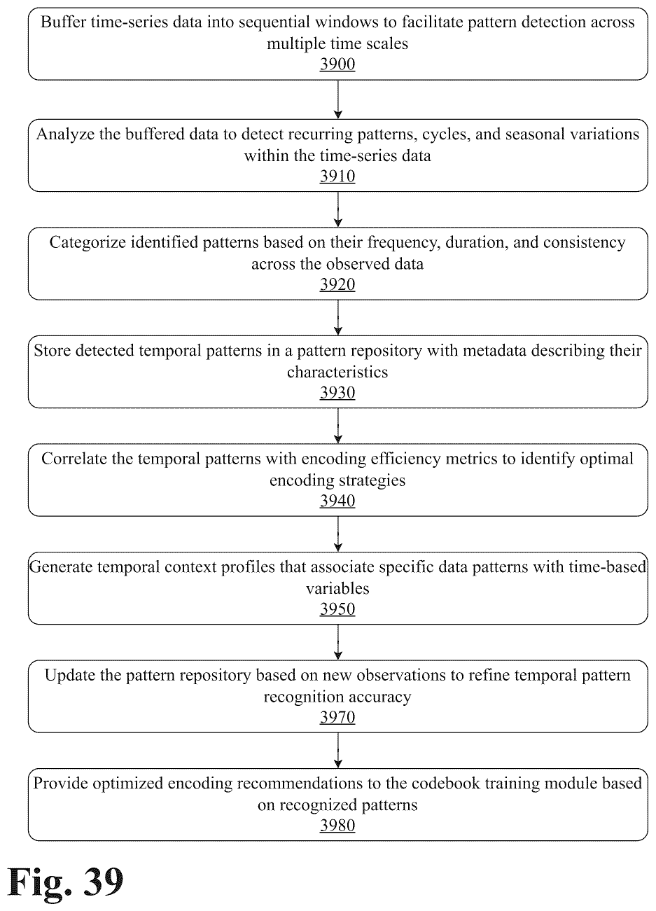

FIG. 39 is a flow diagram illustrating an exemplary method for temporal pattern recognition for data encoding optimization. In a first step 3900, buffer time-series data into sequential windows to facilitate pattern detection across multiple time scales. This buffering step organizes incoming data into chronologically ordered containers that enable analysis at various temporal granularities. The process establishes multiple overlapping time windows, ranging from short-term intervals (seconds to minutes) to medium-term periods (hours to days) and long-term spans (weeks to months). For each time scale, allocate appropriate buffer capacity and implement efficient data structures such as circular buffers or sliding windows to manage the continuous flow of information. This multi-scale buffering approach ensures that patterns can be detected regardless of their temporal frequency. For example, when processing financial market data, establish minute-by-minute buffers for detecting rapid price movements, daily buffers for identifying trading session patterns, and monthly buffers for observing longer-term market trends. The buffering mechanism also handles synchronization of data from multiple sources, ensuring temporal alignment even when data arrives with varying latencies or irregular sampling intervals.

In a step 3910, analyze the buffered data to detect recurring patterns, cycles, and seasonal variations within the time-series data. This analysis employs a suite of statistical and mathematical techniques specifically designed for temporal pattern detection. Apply methods such as autocorrelation analysis to identify self-similarities across time, Fourier transforms to decompose data into frequency components, and wavelet analysis to capture patterns at different scales simultaneously. Machine learning algorithms, including clustering and classification techniques, may supplement these statistical approaches to identify complex patterns that might not be apparent through traditional analysis. For instance, when examining web server traffic logs, the analysis might reveal distinct hourly usage patterns, weekly cycles corresponding to workdays versus weekends, and monthly patterns tied to business cycles. The analysis also identifies anomalies and irregularities that deviate from established patterns, which might indicate special events or changing conditions that require adaptive encoding strategies.

In a step 3920, categorize identified patterns based on their frequency, duration, and consistency across the observed data. This categorization step systematically organizes the detected patterns into a structured taxonomy that facilitates subsequent optimization decisions. Classify patterns according to multiple dimensions, including their periodicity (hourly, daily, weekly, monthly, seasonal, annual), stability (highly consistent, moderately variable, highly irregular), amplitude (the magnitude of variation within the pattern), and prevalence (how frequently the pattern appears in the overall data set). Assign confidence scores to each categorized pattern based on statistical significance metrics such as p-values, correlation coefficients, or machine learning confidence intervals. For example, when categorizing patterns in electric power consumption data, daily usage patterns might be classified as “high-confidence diurnal cycles” with sub-categories for weekday versus weekend variations, while seasonal heating and cooling demands might be classified as “medium-term seasonal patterns” with specifics for different climate zones. This structured categorization creates a knowledge base that informs optimal encoding strategy selection.

In a step 3930, store detected temporal patterns in a pattern repository with metadata describing their characteristics. This storage step creates a persistent knowledge base that accumulates temporal insights over time, enabling increasingly sophisticated encoding optimizations. For each identified pattern, record detailed metadata including its classification category, statistical properties, temporal boundaries, confidence metrics, and historical evolution. Implement an efficient indexing system that allows rapid retrieval of patterns based on various criteria such as time period, data source, or pattern type. The repository employs version control mechanisms to track how patterns evolve over time, maintaining a historical record that can reveal long-term trends or gradual shifts in data characteristics. For instance, in a system processing retail transaction data, the pattern repository might store detailed records of daily shopping patterns, weekly promotional cycles, monthly paycheck-driven spending spikes, and seasonal holiday patterns, each with metadata describing the typical magnitude of variation and statistical confidence in the pattern's consistency.

In a step 3940, correlate the temporal patterns with encoding efficiency metrics to identify optimal encoding strategies. This correlation step establishes the critical connection between observed temporal patterns and concrete encoding optimizations that can improve system performance. For each significant pattern in the repository, conduct experiments to measure how different encoding approaches perform when applied to data exhibiting that pattern. Calculate quantitative metrics such as compression ratio, encoding/decoding speed, error resilience, and resource utilization for each combination of pattern and encoding strategy. Use statistical techniques like regression analysis to identify which encoding parameters have the strongest influence on performance for each pattern type. For example, when processing video surveillance data, correlations might reveal that nighttime footage with minimal movement achieves optimal compression using larger sourceblock sizes and motion-optimized codebooks, while daytime footage with significant activity benefits from smaller sourceblocks and detail-preserving codebooks. These correlations provide the empirical foundation for developing encoding strategies tailored to specific temporal contexts.

In a step 3950, generate temporal context profiles that associate specific data patterns with time-based variables. This profile generation step creates actionable models that connect temporal information (time of day, day of week, month, season) with expected data characteristics and optimal encoding parameters. For each significant temporal context identified in the data, create a comprehensive profile that specifies the probability distribution of data patterns, the typical variation in data composition, and the encoding strategy that has historically provided the best performance for that context. These profiles function as sophisticated lookup tables that enable rapid selection of optimal encoding parameters based on temporal information without requiring full pattern analysis for every encoding decision. For instance, in a system processing smart city sensor data, temporal context profiles might specify that weekday rush hour periods between 7-9 AM typically feature high volumes of traffic sensor data with specific statistical properties, and that this data is most efficiently encoded using a particular combination of codebook and sourceblock size optimized for those properties.

In a step 3970, update the pattern repository based on new observations to refine temporal pattern recognition accuracy. This updating step implements a continuous learning process that allows the system to adapt to evolving data characteristics and improve its pattern recognition capabilities over time. As new data is processed, compare observed patterns against the existing repository to identify confirmations, variations, or contradictions of previously established patterns. When substantial differences are detected, update the repository entries to reflect the new information, adjusting confidence scores and statistical parameters accordingly. For patterns that show drift or evolution over time, implement trend analysis to predict future changes and proactively adapt encoding strategies. For example, in processing network traffic for a growing organization, regular updates might track how usage patterns evolve as the employee base expands and new applications are deployed, ensuring that encoding strategies remain optimized even as the underlying data characteristics change. This continuous refinement process ensures that the pattern recognition system becomes increasingly accurate and effective over time.

In a step 3980, provide optimized encoding recommendations to the codebook training module based on recognized patterns. This recommendation step translates the accumulated temporal knowledge into concrete directives that guide the codebook generation and selection processes. For each identified temporal context, formulate specific recommendations regarding codebook composition, sourceblock sizing, and encoding parameters that will maximize efficiency for data in that context. These recommendations include quantitative specifications such as optimal bit allocations, entropy coding parameters, and pattern prioritization guidelines tailored to the statistical properties of each temporal context. The recommendations are communicated through a structured interface that allows the codebook training module to incorporate the temporal insights without requiring detailed knowledge of the pattern recognition mechanisms. For example, recommendations for encoding financial market data might specify that pre-market trading hours should use codebooks optimized for low-volume, high-volatility patterns, while regular trading hours should use different codebooks optimized for high-volume, more predictable patterns. These targeted recommendations ensure that the encoding process leverages the full value of the temporal insights gained through pattern recognition.

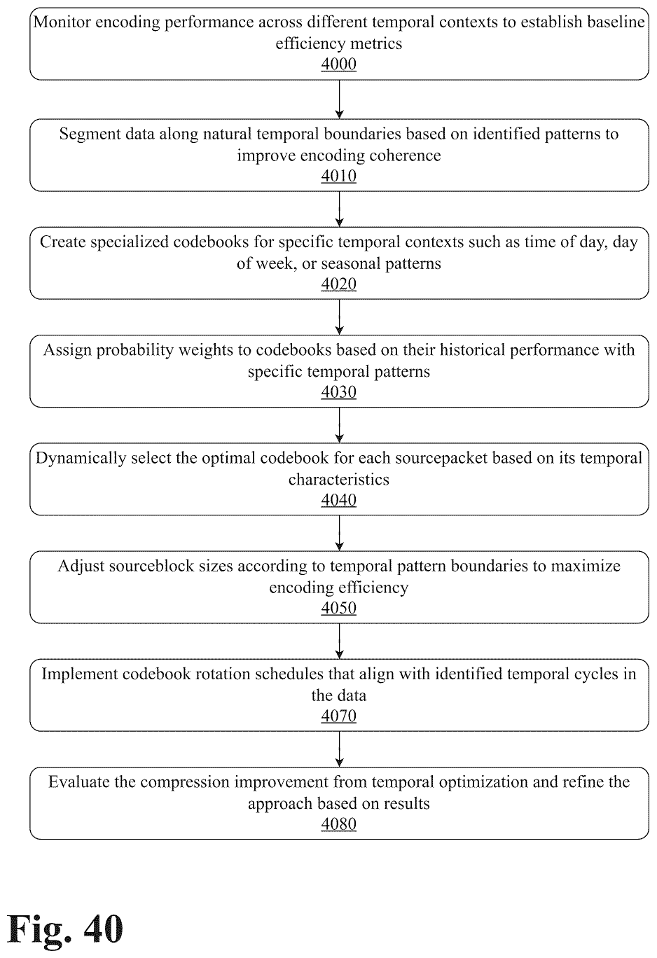

FIG. 40 is a flow diagram illustrating an exemplary method for temporally optimizing codebooks for data encoding. In a first step 4000, monitor encoding performance across different temporal contexts to establish baseline efficiency metrics. This monitoring step creates a comprehensive performance baseline that quantifies how encoding efficiency varies across different temporal contexts before optimization. Gather detailed metrics on compression ratio, encoding speed, decoding speed, and resource utilization while processing data from various time periods. Track these metrics in relation to specific temporal contexts such as time of day, day of week, or seasonal periods. For example, when monitoring network traffic encoding, measure how compression performance differs between business hours, overnight periods, weekdays, and weekends. Record these baseline measurements in a structured database that allows for statistical analysis and pattern identification. Include sufficient metadata with each measurement to enable correlation with specific data characteristics and temporal contexts. This baseline serves as the foundation for measuring the impact of subsequent optimization efforts and identifying which temporal contexts offer the greatest opportunity for improvement.

In a step 4010, segment data along natural temporal boundaries based on identified patterns to improve encoding coherence. This segmentation step divides incoming data streams at points where temporal context shifts occur, rather than using arbitrary fixed-size divisions. Analyze the data to identify transition points where statistical properties, data composition, or pattern characteristics change significantly, indicating a shift in temporal context. For instance, in video surveillance footage, identify natural boundaries where lighting conditions change dramatically between day and night, or in financial transaction data, segment at the boundaries between regular trading hours and after-hours trading periods. Implement adaptive segmentation algorithms that can recognize these natural boundaries automatically by monitoring changes in running statistics, entropy measures, or pattern match confidence. The segmentation may occur at multiple levels, from macro-level divisions (such as separating weekday from weekend data) to micro-level boundaries (such as segmenting different phases of a daily activity cycle). By aligning data segments with natural temporal boundaries, each segment becomes more internally consistent, enabling more efficient encoding.

In a step 4020, create specialized codebooks for specific temporal contexts such as time of day, day of week, or seasonal patterns. This codebook creation step develops custom encoding dictionaries optimized for the unique characteristics of data within each identified temporal context. For each significant temporal context, analyze the statistical properties of the associated data, including frequency distributions, entropy characteristics, and recurring patterns. Using this analysis, generate specialized codebooks that allocate more efficient encodings to the data patterns most common within each context. For example, create distinct codebooks for morning, afternoon, and evening periods in user activity logs, with each codebook optimized for the typical usage patterns during those times. Similarly, develop separate codebooks for weekday and weekend data in retail transaction systems, reflecting the different purchasing behaviors observed during these periods. For seasonal data, create specialized codebooks for each season, quarter, or other relevant temporal division. The creation process employs information theory principles such as Huffman coding or arithmetic coding to ensure optimal bit allocation based on the probability distribution of data patterns within each context.

In a step 4030, assign probability weights to codebooks based on their historical performance with specific temporal patterns. This weighting step creates a quantitative framework for codebook selection that reflects empirical performance data rather than just theoretical optimization. For each combination of codebook and temporal pattern, calculate performance metrics based on historical encoding results. These metrics might include achieved compression ratio, encoding speed, error resilience, and other relevant factors. Convert these raw performance metrics into normalized probability weights that indicate the relative effectiveness of each codebook for each temporal pattern. For example, if a “business hours” codebook consistently achieves 15% better compression than alternatives when encoding weekday network traffic between 9 AM and 5 PM, assign it a correspondingly high probability weight for that temporal context. Maintain these weights in a dynamic database that is continuously updated as new performance data becomes available. The weighting system may employ Bayesian statistics to balance prior knowledge with new observations, ensuring that the weights evolve to reflect changing data characteristics while remaining stable enough for reliable decision-making.

In a step 4040, dynamically select the optimal codebook for each sourcepacket based on its temporal characteristics. This selection step applies the knowledge gained from previous steps to make real-time decisions about which codebook to use for encoding each incoming sourcepacket. Examine the temporal metadata associated with each sourcepacket, such as timestamps or sequence information, to determine its temporal context. Reference this context against the probability weights established in the previous step to identify the codebook most likely to provide optimal encoding performance. Implement a selection algorithm that balances encoding efficiency against the overhead of frequent codebook switching. For example, when processing sensor data from an IoT network, dynamically switch between “daytime” and “nighttime” codebooks based on the timestamp of each sourcepacket, using the probability weights to resolve edge cases near dawn and dusk. In cases where a sourcepacket spans multiple temporal contexts, either select the codebook with the highest overall probability of success or segment the sourcepacket further to apply different codebooks to different portions. This dynamic selection ensures that each sourcepacket is encoded using the most appropriate codebook for its specific temporal context.

In a step 4050, adjust sourceblock sizes according to temporal pattern boundaries to maximize encoding efficiency. This adjustment step optimizes the granularity of data division to align with the characteristics of different temporal contexts. Analyze how encoding efficiency varies with different sourceblock sizes across various temporal contexts, identifying optimal size ranges for each context. For data with high temporal coherence and predictability, configure larger sourceblock sizes to capitalize on redundancies across broader data spans. For volatile or rapidly changing data, implement smaller sourceblock sizes to capture fine-grained variations more effectively. For example, in financial market data, use smaller sourceblocks during high-volatility trading periods to capture rapid price movements accurately, while using larger sourceblocks during stable overnight periods to maximize compression of relatively unchanging data. Implement adaptive algorithms that dynamically adjust sourceblock sizes in response to detected changes in data stability or pattern consistency. This temporal awareness in sourceblock sizing complements the codebook optimization, creating a multi-dimensional approach to temporal encoding efficiency.

In a step 4070, implement codebook rotation schedules that align with identified temporal cycles in the data. This implementation step creates systematic plans for codebook transitions that anticipate and prepare for known temporal patterns rather than merely reacting to them. Based on the identified temporal cycles in the data, develop schedules that specify when to switch between different codebooks to maintain optimal encoding efficiency. For example, in a system processing enterprise network traffic, implement a weekday schedule that rotates from “morning,” to “midday,” to “evening,” to “overnight” codebooks at specific times aligned with typical usage pattern shifts. Similarly, implement seasonal rotation schedules for data with annual cycles, such as energy consumption or retail sales. Incorporate predictive elements in these schedules to account for anticipated pattern shifts before they occur, such as pre-loading holiday-optimized codebooks before major shopping events. The rotation schedules may include hysteresis mechanisms to prevent rapid oscillation between codebooks during transitional periods. By aligning codebook rotations with natural temporal cycles, encoding efficiency remains optimized even as data characteristics evolve predictably over time.

In a step 4080, evaluate the compression improvement from temporal optimization and refine the approach based on results. This evaluation step completes the feedback loop by measuring the actual performance gains achieved through temporal optimization and using those measurements to guide further improvements. Conduct systematic comparisons between the temporally-optimized encoding approach and baseline methods using consistent test data sets that span multiple temporal contexts. Calculate key performance metrics including compression ratio improvements, encoding/decoding speed changes, and resource utilization differences. Perform statistical analysis to determine which aspects of the temporal optimization contribute most significantly to performance gains. For example, quantify whether codebook specialization, sourceblock size adjustment, or rotation scheduling provides the greatest benefit for specific data types. Based on these findings, refine the overall temporal optimization approach by enhancing high-value elements and modifying or eliminating components that provide minimal benefit. This continuous evaluation and refinement process ensures that the temporal optimization strategy evolves to maximize real-world performance rather than theoretical advantages. Over time, this iterative improvement leads to increasingly sophisticated temporal optimization that delivers substantial encoding efficiency gains compared to non-temporally-aware approaches.

### Exemplary Computing Environment

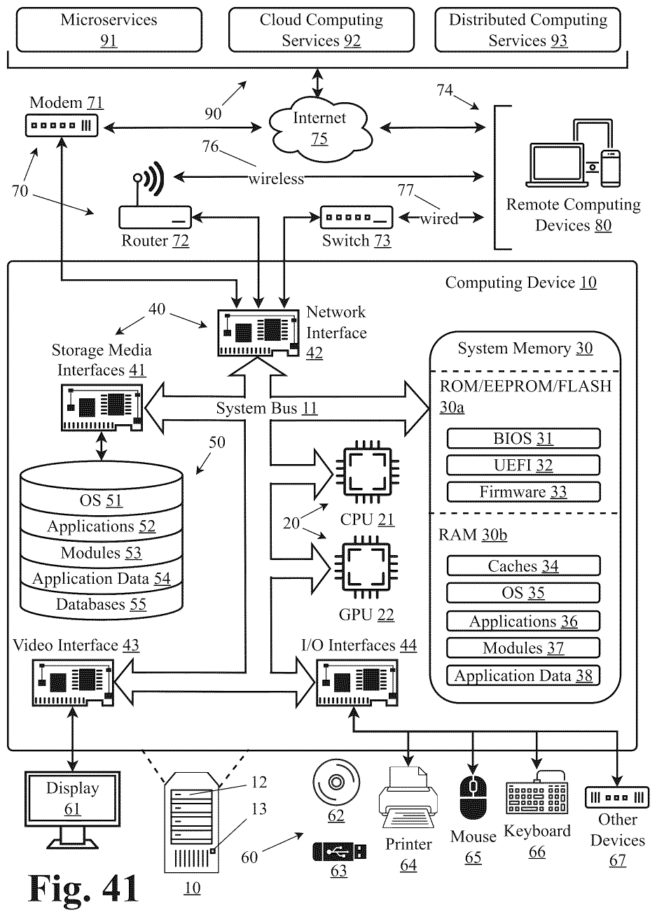

FIG. 41 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally-accessible data ports or connections 12 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed or the processing mechanisms employed therein, but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions. Further, computing device 10 may comprise one or more specialized processors such as a graphics processing unit (GPU) 22 configured to accelerate processing of computer graphics and images via a large array of specialized processing cores arranged in parallel. The term processor may further include: neural processing units (NPUs) or neural computing units optimized for machine learning and artificial intelligence workloads using specialized architectures and data paths; tensor processing units (TPUs) designed to efficiently perform matrix multiplication and convolution operations used heavily in neural networks and deep learning applications; application-specific integrated circuits (ASICs) implementing custom logic for domain-specific tasks; application-specific instruction set processors (ASIPs) with instruction sets tailored for particular applications; field-programmable gate arrays (FPGAs) providing reconfigurable logic fabric that can be customized for specific processing tasks; processors operating on emerging computing paradigms such as quantum computing, optical computing, mechanical computing (e.g., using nanotechnology entities to transfer data), and so forth. Depending on configuration, computing device 10 may comprise one or more of any of the above types of processors in order to efficiently handle a variety of general purpose and specialized computing tasks. The specific processor configuration may be selected based on performance, power, cost, or other design constraints relevant to the intended application of computing device 10.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed, and includes memory types such as read only memory (ROM), electronically-erasable programmable memory (EEPROM), and rewritable solid state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI), which is a modern replacement for BIOS that supports larger hard drives, faster boot times, more security features, and provides native support for graphics and mouse cursors. Non-volatile memory 30a may also be used to store firmware comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM), and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories which operate at a higher clock speed and are typically placed on the same IC as the processors to improve performance.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10 to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. One or more input/output (I/O) interfaces 44 provide the necessary support for communications between computing device 10 and any external peripherals and accessories 60. For wireless communications, the necessary radio-frequency hardware and firmware may be connected to I/O interface 44 or may be integrated into I/O interface 44.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, BOSQL databases, and graph databases.

Applications (also known as computer software or software applications) are sets of programming instructions designed to perform specific tasks or provide specific functionality on a computer or other computing devices. Applications are typically written in high-level programming languages such as C++, Java, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing device and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network. Here, modem 71 is shown connecting computing device 10 to both remote computing devices 80 and cloud-based services 90 via the Internet 75. While modem 71, router 72, and switch 73 are shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices.

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92, but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is Docker, which is widely used in software development and deployment. Containerization, particularly with open-source technologies like Docker and container orchestration systems like Kubernetes, is a common approach for deploying and managing applications. Containers are created from images, which are lightweight, standalone, and executable packages that include application code, libraries, dependencies, and runtime. Images are often built from a Dockerfile or similar, which contains instructions for assembling the image. Dockerfiles are configuration files that specify how to build a Docker image. Systems like Kubernetes also support containerd or CRI-O. They include commands for installing dependencies, copying files, setting environment variables, and defining runtime configurations. Docker images are stored in repositories, which can be public or private. Docker Hub is an exemplary public registry, and organizations often set up private registries for security and version control using tools such as Hub, JFrog Artifactory and Bintray, Github Packages or Container registries. Containers can communicate with each other and the external world through networking. Docker provides a bridge network by default, but can be used with custom networks. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, main frame computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, gRPC, or message queues such as Kafka. Microservices 91 can be combined to perform more complex processing tasks.

Cloud computing services 92 are delivery of computing resources and services over the Internet 75 from a remote location. Cloud computing services 92 provide additional computer hardware and storage on as-needed or subscription basis. Cloud computing services 92 can provide large amounts of scalable data storage, access to sophisticated software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over the Internet on a subscription basis.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

The skilled person will be aware of a range of possible modifications of the various aspects described above. Accordingly, the present invention is defined by the claims and their equivalents.

What is claimed is:

1. A computer system comprising a hardware memory, wherein the computer system is configured to execute software instructions stored on nontransitory machine-readable storage media that:
analyze time-series data to identify recurring temporal patterns across multiple time scales;
select a list of codebooks for encoding a plurality of sourcepackets based on the identified temporal patterns, each sourcepacket comprising a sourcepacket identifier and one or more of the identified temporal patterns, the list comprising a codebook identifier for each codebook;
for each sourcepacket:
encode the sourcepacket with a codebook in the list of codebooks dynamically selected based on the sourcepacket's temporal characteristics;
associate the sourcepacket identifier with the encoded sourcepacket;
associate the codebook identifier of the codebook which produced the encoded sourcepacket with the sourcepacket identifier; and
send a data pair comprising the respective sourcepacket identifier and its associated codebook identifier to a combiner.

2. The system of claim 1, wherein the codebooks used to encode the data are combined as a single codebook.

3. The system of claim 1, wherein the data structure further comprises a copy of the stored encoded sourcepacket associated with each sourcepacket identifier.

4. The system of claim 1, wherein the sourcepacket identifier is a universal unique identifier (UUID).

5. The system of claim 1, wherein the codebook identifier is a universal unique identifier (UUID).

6. A method for codebook-based data encoding, comprising the steps of:
analyze time-series data to identify recurring temporal patterns across multiple time scales;
select a list of codebooks for encoding a plurality of sourcepackets based on the identified temporal patterns, each sourcepacket comprising a sourcepacket identifier and one or more of the identified temporal patterns, the list comprising a codebook identifier for each codebook;
for each sourcepacket:
encode the sourcepacket with a codebook in the list of codebooks dynamically selected based on the sourcepacket's temporal characteristics;
associate the sourcepacket identifier with the encoded sourcepacket;
associate the codebook identifier of the codebook which produced the encoded sourcepacket with the sourcepacket identifier; and
send a data pair comprising the respective sourcepacket identifier and its associated codebook identifier to a combiner.

7. The method of claim 6, further comprising the step of combining the codebooks used to encode the data into a single codebook.

8. The method of claim 6, further comprising the step of including a copy of the stored encoded sourcepacket associated with each sourcepacket identifier in the data structure.

9. The method of claim 6, wherein the sourcepacket identifier is a universal unique identifier (UUID).

10. The method of claim 6, wherein the codebook identifier is a universal unique identifier (UUID).
